(19) United States
(12) Patent Application Publication
(10) Pub. No.: US 2025/0079281 A1
(43) Pub. Date: Mar. 6, 2025

(54) PACKAGE SUBSTRATE EMPLOYING FILM SUBSTRATE AND AN OUTER PRE-IMPREGNATED (PPG) SUBSTRATE(S) TO SUPPORT HIGH DENSITY BUMP AND WIRE BOND CONNECTIONS, AND RELATED HYBRID INTEGRATED CIRCUIT (IC) PACKAGES AND FABRICATION METHODS

(71) Applicant: QUALCOMM Incorporated, San Diego, CA (US)

(72) Inventors: Hong Bok We, San Diego, CA (US); Joan Rey Villarba Buot, Escondido, CA (US); Sang-Jae Lee, San Diego, CA (US); Zhijie Wang, San Diego, CA (US); Michelle Yejin Kim, Carlsbad, CA (US)

(21) Appl. No.: 18/458,242

(22) Filed: Aug. 30, 2023

(51) Int. Cl. H01L 23/498; H01L 21/48; H01L 23/00; H01L 25/065

(52) U.S. Cl. CPC H01L 23/49822; H01L 21/4857; H01L 24/16; H01L 24/48; H01L 25/0657; H01L 23/49894; H01L 24/32; H01L 24/73; H01L 2224/16227; H01L 2224/32145; H01L 2224/48091; H01L 2224/48228; H01L 2224/73253; H01L 2224/73265; H01L 2225/0651; H01L 2225/06517; H01L 2225/06565

(57) ABSTRACT

Hybrid package substrates employing film metallization layers with outer pre-impregnated (PPG) region(s) to support high density bump and wire bond connections for respective bump and wire bond connected dies in the IC package, and related hybrid integrated circuit (IC) packages and fabrication methods are disclosed. The package substrate includes film metallization layers of a softer, flexible material that can more easily be patterned to support formation of high density, reduced pitch metal interconnects to support finer bump pitch connections to a bottom, first die(s) in a die region of the package substrate. The package substrate also includes one or more PPG regions a PPG metallization layer(s) adjacent to the die region of the package substrate that reinforces the film metallization layers and also supports the formation of wire bond pads for wire bond connections to an upper, second die(s) in the hybrid IC package.

### BACKGROUND

### I. Field of the Disclosure

The field of the disclosure relates to integrated circuit (IC) packages, and more particularly to hybrid IC packages that include stacked dies and use of bump and wire bonding connections to electrically couple respective lower and upper dies to the package substrate.

### II. Background

Integrated circuits (ICs) are the cornerstone of electronic devices. ICs are packaged in an IC package, also called a “semiconductor package” or “chip package.” The IC package includes one or more semiconductor dice (“dies” or “dice”) as an IC(s) that are mounted on and electrically coupled to a package substrate to provide physical support and an electrical interface to the die(s). The package substrate includes one or more metallization layers that include electrical traces (e.g., metal lines) with vertical interconnect accesses (vias) coupling the electrical traces together between adjacent metallization layers to provide electrical interfaces between the die(s). The die(s) is electrically interfaced to metal interconnects exposed in a top or outer layer of the package substrate to electrically couple the semiconductor die(s) to the electrical traces of the package substrate. The package substrate includes an outer metallization layer coupled to external metal interconnects (e.g., solder bumps) to provide an external interface between the die(s) in the IC package for mounting the IC package on a circuit board to interface the die(s) with other circuitry.

Some IC packages are known as “hybrid” IC packages which include multiple dies for different purposes or applications. For example, a hybrid IC package may include a modem die as part of a front-end circuitry for supporting a communications interface. The hybrid IC package could also include one or more memory dies that provide memory to support data storage and access by the modem die, such as for buffering and outgoing data to be modulated and/or demodulated data. Thus, in these hybrid IC packages, it is conventional to stack the multiple dies on top of each other in the IC package in a vertical direction. The bottom-most die that is directly adjacent to the package substrate of the IC package is electrically coupled through die interconnects to metal interconnects in an upper metallization layer of the package substrate. For example, the die interconnects may include solder bumps or higher density ball-grid array (BGA) interconnects (e.g., flip-chip BGAs (FCBGAs)) as part of the dies that are coupled to metal interconnects in the package substrate to physically and electrically connect the bottom die to the package substrate. Other stacked dies that are not directly adjacent to the package substrate of the IC package can be electrically coupled by wire bonds to the upper metallization layer of the package substrate. Die-to-die (D2D) electrical connections can be made between the stacked dies through electrical connections formed in the metallization layers of the package substrate.

It is important that the package substrate be fabricated to provide sufficient strength and stability to limit or avoid warpage to the IC package in hybrid IC packages due to the increased height of the IC package due to the stacked dies.

### SUMMARY OF THE DISCLOSURE

Aspects disclosed herein include a package substrate employing a film substrate and an outer pre-impregnated (PPG) substrate(s) to support high density bump and wire bond connections for respective bump and wire bond connected dies in the IC package. Related hybrid integrated circuit (IC) packages and fabrication methods are also disclosed. The package substrate includes a film substrate that has one or more film metallization layers each with a film insulating layer of a softer, flexible material that does not include a harder reinforcing material, such as PPG material. Thus, the film insulating layers can more easily be patterned to support formation of high density, reduced pitch metal interconnects to support finer bump pitch for a higher-density die(s). In this manner, the film metallization layers of the film substrate can support a higher density bump connection to a first, bottom die(s) (e.g., a flip-chip) that has high density bump connections (e.g., flip-chip ball-grid arrays (FCBGAs)). The softer material film insulating layers also support compression bonding to the first, bottom die(s). For example, the film metallization layers can be formed as ajinomoto build-up film (ABF) layers of a softer polyimide material. A first, bottom die(s) can be coupled to first metal interconnects exposed from an outer film metallization layer of the film substrate in a first, die region of the package substrate to couple the first, bottom die(s) to the package substrate as part of the hybrid IC package. However, it may not be feasible to form wire bond pads on the softer material, outer film metallization layer of the film substrate to support wire bond connections to a second, upper die(s) to the package substrate in the hybrid IC package. This is due to the material properties of the flexible, softer material used to form the film insulating layers in the film substrate that may not support wire bonding techniques such as heat, pressure, and/or ultrasonic energy.

In this regard, in exemplary aspects, to also support wire bond pads on the package substrate to support wire bond connections to the second, upper die(s) in the hybrid IC package, the package substrate also includes one or more PPG substrates in a second region of the film substrate outside of and laterally adjacent to the first, die region of the package substrate. A PPG substrate is a substrate that includes a reinforcing material, such as woven fiberglass or other fibers, impregnated in a resin matrix, such as an epoxy to provide a firmer, stronger and less flexible substrate. The combination of the resin and fibers can be partially cured or “pre-impregnated” before being used in a fabrication process. The PPG substrate(s) includes one or more PPG metallization layers that are coupled (e.g., formed) adjacent to the outer film metallization layer of the film substrate, wherein each PPG metallization layer includes a PPG insulating layer and metal layer with metal interconnects. The PPG metallization layer(s) not only reinforces the film metallization layers of the film substrate for increased strength and stability to reduce or minimize warpage, but also supports the formation of wire bond pads in the second region adjacent to the first, die region that can better withstand wire bonding techniques. In this regard, wire bond pads can be formed as part of or in contact with metal interconnects exposed from an outer PPG metallization layer in the PPG substrate(s) to support wire bond connections between the second, upper die(s) of the hybrid IC package and its package substrate. The metal interconnects of the outer PPG metallization layer are coupled to metal interconnects of the film metallization layer(s) in the film substrate to facilitate electrical coupling of the second, upper die(s) to the film substrate of the package substrate. In this manner, the package substrate is a hybrid substrate in that it includes the film substrate of film metallization layers of softer material to support finer pitch metal interconnects for finer bump pitch for connection to a first, bottom die(s) in the first, die region, but also includes a PPG substrate(s) of a PPG metallization layer(s) in the second region, outside the die region, to provide strength and stability to the film substrate and support wire bond pads for wire bond connections to a second, upper die(s).

In this regard, in one exemplary aspect, a package substrate is provided. The package substrate comprises a first substrate comprising a first film metallization layer comprising a first surface and extending in a first direction. The first film metallization layer comprises a first film insulating layer and a first metal layer, comprising: a plurality of first metal interconnects exposed from the first surface in a first region of the first film metallization layer, and a plurality of second metal interconnects exposed from the first surface in a second region of the first film metallization layer adjacent to the first region in the first direction. The package substrate also comprises a second substrate comprising a first PPG metallization layer adjacent to the first surface in the second region. The first PPG metallization layer comprises a second surface and a second insulating layer comprising a PPG material and a second metal layer comprising: a plurality of first metal pads exposed from the second surface.

In another exemplary aspect, a method of fabricating a package substrate is provided. The method comprises forming a first substrate comprising forming a first film metallization layer comprising a first surface and extending in a first direction, which comprises forming a first film insulating layer, forming a first metal layer, forming a plurality of first metal interconnects in the first metal layer exposed from the first surface in a first region of the first film metallization layer, and forming a plurality of second metal interconnects in the first metal layer exposed from the first surface in a second region of the first film metallization layer adjacent to the first region in the first direction. The method also comprises forming a second substrate comprising forming a first PPG metallization layer having a second surface, which comprises forming a second insulating layer comprising a PPG material, forming a second metal layer, and forming a plurality of first metal pads from the second metal layer exposed from the second surface. The method also comprises coupling the second substrate to the first substrate in a second direction orthogonal to the first direction in the second region of the first film metallization layer.

In another exemplary aspect, an IC package is provided. The IC package comprises a package substrate. The package substrate comprises a first substrate comprising a first film metallization layer comprising a first surface and extending in a first direction. The first film metallization layer comprises a first film insulating layer and a first metal layer, comprising: a plurality of first metal interconnects exposed from the first surface in a first region of the first film metallization layer, and a plurality of second metal interconnects exposed from the first surface in a second region of the first film metallization layer adjacent to the first region in the first direction. The package substrate also comprises a second substrate comprising a first PPG metallization layer adjacent to the first surface in the second region. The first PPG metallization layer comprises a second surface and a second insulating layer comprising a PPG material and a second metal layer comprising: a plurality of first metal pads exposed from the second surface. The IC package also comprises a first die comprising a plurality of die interconnects each connected to a first metal interconnect of the plurality of first metal interconnects. The IC package also comprises a second die adjacent to the first die such that the first die is between the second die and the package substrate in a second direction orthogonal to the first direction. The IC package also comprises a plurality of wire bonds each connected to the second die and a first metal pad of the plurality of first metal pads.

### BRIEF DESCRIPTION OF THE FIGURES

FIGS. 1A and 1B are a side view and close-up, partial side view, respectively, of an exemplary hybrid integrated circuit (IC) package that includes a cored package substrate that includes a film substrate with one or more film metallization layers to support higher density bump pitch for die connections to a first, bottom die(s) in a first, die region in the film substrate, and a pre-impregnated (PPG) substrate of one or more PPG metallization layers in a second region of the film substrate outside the die region, to reinforce the film substrate and support wire bond connections to a second, upper die(s) in the hybrid IC package;

FIG. 1C is the side view of the hybrid IC package in FIG. 1A;

FIG. 1D is a top view of the hybrid IC package in FIG. 1A illustrating the metal interconnects of finer bump pitch exposed from an outer film metallization layer of the film substrate in the first, die region of the package substrate;

FIG. 1E is a top view of the hybrid IC package in FIG. 1A illustrating the wire bond pads exposed from an outer PPG metallization layer of a PPG substrate(s) in the second region of the film substrate;

FIGS. 2A and 2B are a side view and close-up, partial side view, respectively, of an exemplary hybrid IC package that includes a coreless package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package; FIG. 2C is the side view of the hybrid IC package in FIG. 2A;

FIG. 2D is a top view of the hybrid IC package in FIG. 2A illustrating the metal interconnects of finer bump pitch exposed from an outer film metallization layer of the film substrate of the package substrate;

FIG. 2E is a top view of the hybrid IC package in FIG. 2A illustrating the wire bond pads exposed from an outer PPG metallization layer in the PPG substrate of the package substrate;

FIG. 3A and 3B is a flowchart illustrating an exemplary fabrication process of fabricating a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates in FIGS. 1A-1E and 2A-2E;

FIGS. 4A-4D is a flowchart illustrating another exemplary fabrication process of fabricating a cored package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates in FIGS. 1A-1E;

FIGS. 5A-5H are exemplary fabrication stages during fabrication of a package substrate according to the fabrication process in FIGS. 4A-4D;

FIGS. 6A-6C is a flowchart illustrating another exemplary fabrication process of fabricating a coreless package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates in FIGS. 2A-2E;

FIGS. 7A-7F are exemplary fabrication stages during fabrication of a package substrate according to the fabrication process in FIGS. 6A-6C;

FIG. 8 is a block diagram of an exemplary wireless communications device that includes radio-frequency (RF) components that can include a hybrid IC package(s) that includes a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E, 2A-2E, 5G and 5H, and 7E and 7F, and that can be fabricated according to the exemplary fabrication processes in FIGS. 3A-3B. 4A-4D, and 6A-6C; and

FIG. 9 is a block diagram of an exemplary processor-based system that can include components that can include a hybrid IC package(s) that includes a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E, 2A-2E, 5G and 5H, and 7E and 7F, and that can be fabricated according to the exemplary fabrication processes in FIGS. 3A-3B, 4A-4D, and 6A-6C.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed herein include a package substrate employing a film substrate and an outer pre-impregnated (PPG) substrate(s) to support high density bump and wire bond connections for respective bump and wire bond connected dies in the IC package. Related hybrid integrated circuit (IC) packages and fabrication methods are also disclosed. The package substrate includes a film substrate that has one or more film metallization layers each with a film insulating layer of a softer, flexible material that does not include a harder reinforcing material, such as PPG. Thus, the film insulating layers can more easily be patterned to support formation of high density, reduced pitch metal interconnects to support finer bump pitch for a higher-density die(s). In this manner, the film metallization layers of the film substrate can support a higher density bump connection to a first, bottom die(s) (e.g., a flip-chip) that has high density bump connections (e.g., flip-chip ball-grid arrays (FCBGAs)). The softer material film insulating layers also support compression bonding to the first, bottom die(s). For example, the film metallization layers can be formed as ajinomoto build-up film (ABF) layers of a softer polyimide material. A first, bottom die(s) can be coupled to first metal interconnects exposed from an outer film metallization layer of the film substrate in a first, die region of the package substrate to couple the first, bottom die(s) to the package substrate as part of the hybrid IC package. However, it may not be feasible to form wire bond pads on the softer material, outer film metallization layer of the film substrate to support wire bond connections to a second, upper die(s) to the package substrate in the hybrid IC package. This is due to the material properties of the flexible, softer material used to form the film insulating layers in the film substrate that may not support wire bonding techniques such as heat, pressure, and/or ultrasonic energy.

In this regard, in exemplary aspects, to also support wire bond pads on the package substrate to support wire bond connections to the second, upper die(s) in the hybrid IC package, the package substrate also includes one or more PPG substrates in a second region of the film substrate outside of and laterally adjacent to the first, die region of the package substrate. A PPG substrate is a substrate that includes a reinforcing material, such as woven fiberglass or other fibers, impregnated in a resin matrix, such as an epoxy to provide a firmer, stronger and less flexible substrate. The combination of the resin and fibers can be partially cured or “pre-impregnated” before being used in a fabrication process. The PPG substrate(s) includes one or more PPG metallization layers that is coupled (e.g., formed) adjacent to the outer film metallization layer of the film substrate, wherein each PPG metallization layer includes a PPG insulating layer and metal layer with metal interconnects. The PPG metallization layer(s) not only reinforces the film metallization layers of the film substrate for increased strength and stability to reduce or minimize warpage, but also supports the formation of wire bond pads in the second region adjacent to the first, die region that can better withstand wire bonding techniques. In this regard, wire bond pads can be formed as part of or in contact with metal interconnects exposed from an outer PPG metallization layer in the PPG substrate(s) to support wire bond connections between the second, upper die(s) of the hybrid IC package and its package substrate. The metal interconnects of the outer PPG metallization layer are coupled to metal interconnects of the film metallization layer(s) in the film substrate to facilitate electrical coupling of the second, upper die(s) to the film substrate of the package substrate. In this manner, the package substrate is a hybrid substrate in that it includes the film substrate of film metallization layers of softer material to support finer pitch metal interconnects for finer bump pitch for connection to a first, bottom die(s) in the first, die region, but also includes a PPG substrate(s) of a PPG metallization layer(s) in the second region, outside the die region, to provide strength and stability to the film substrate and support wire bond pads for wire bond connections to a second, upper die(s).

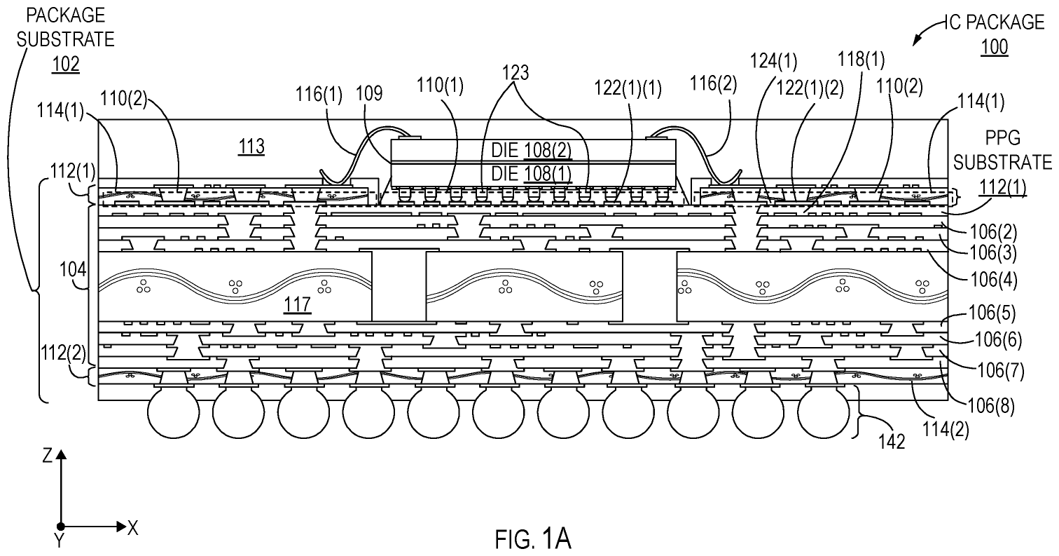

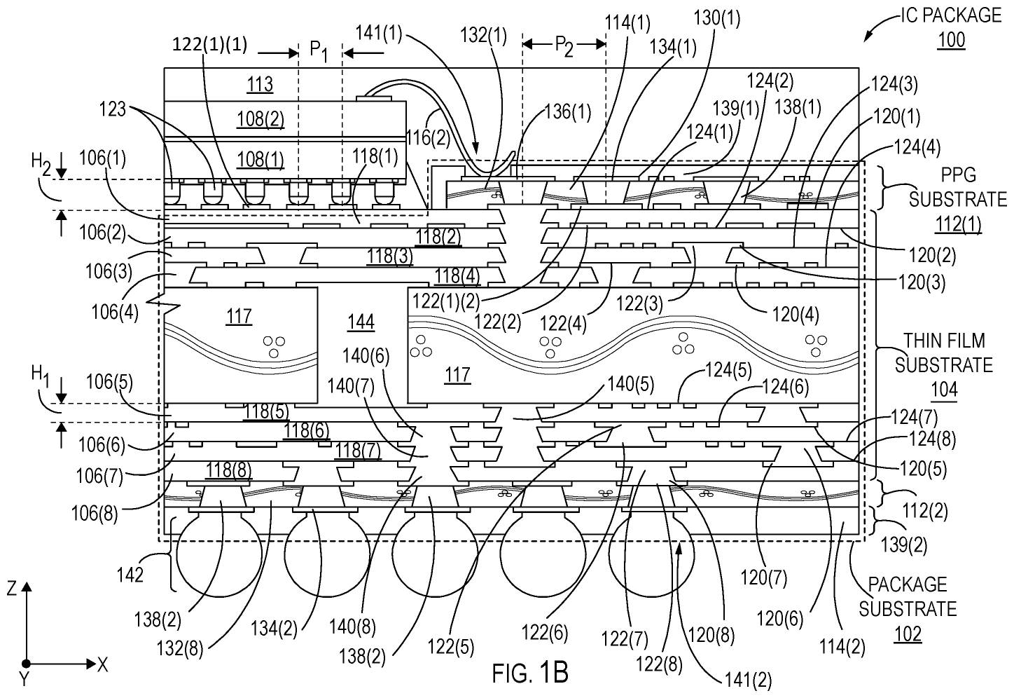

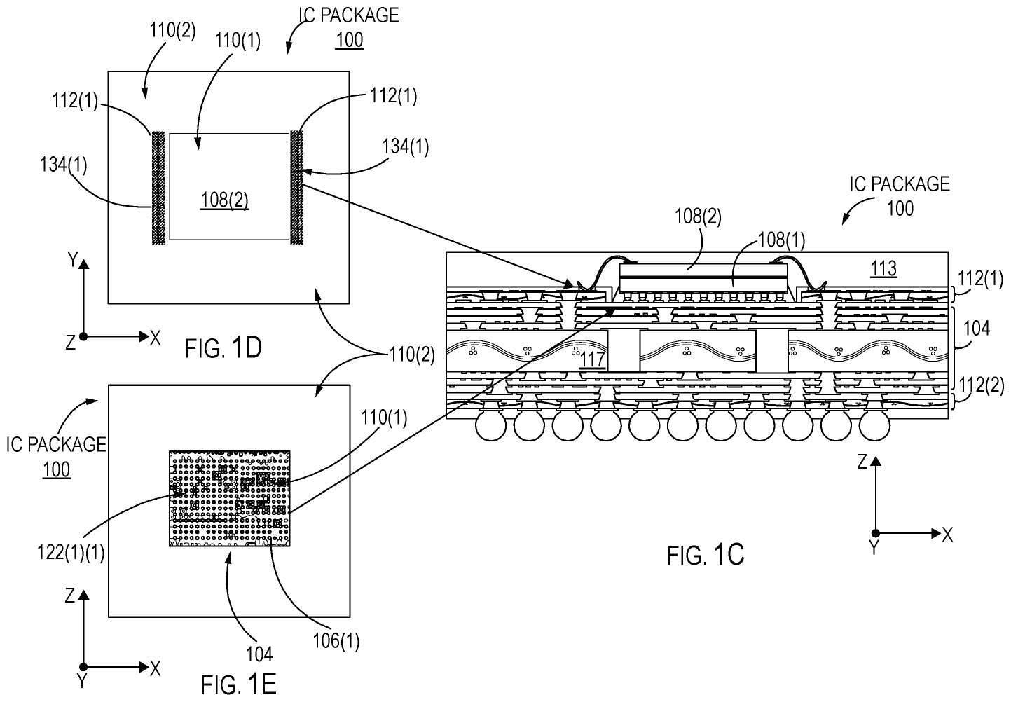

In this regard, FIGS. 1A and 1B are a side view and close-up, partial side view, respectively, of an exemplary hybrid IC package 100 (also referred to as “IC package 100”) that includes a package substrate 102 that includes a first, film substrate 104. A film substrate 104 is a substrate that is formed from one or more film insulating layers built upon each other to form respective metallization layers in a fabrication process. The film insulating layers may have a reduced height or thickness available through an additive fabrication process, as opposed to other types of insulating layers used in package substrates, such as a laminated substrate that includes separately formed insulating layers that are then laminated together. As discussed in more detail below, the film substrate 104 of the package substrate 102 includes a plurality of film metallization layers 106(1)-106(8) to support higher density bump pitch for a die connection to a first, bottom die 108(1) in a first, die region 110(1) of the film substrate 104. The film metallization layers 106(1)-106(8) extend in a first, horizontal direction (X-axis and/or Y-axis direction(s)). By “film” metallization layer, this means that the film metallization layer is made from one or more film insulating layers of a dielectric material (e.g., a plastic, polymer, ceramic) that is disposed on a surface as film in a fabrication process and then processed. By “film insulating layer,” it is meant that such layer is a sheet layer or coating of a dielectric, insulating material that disposed on a surface as a layer, which may then be processed. The first, outer film metallization layer 106(1) has a film insulating layer that can be a thin film and is made from a softer, more flexible material. For example, the first, outer film metallization layer 106(1), as well as any of the other film metallization layers 106(2)-106(8), can be formed as ajinomoto build-up film (ABF) layers of a softer polyimide material. In this manner, the first, outer film metallization layer 106(1) can support patterning of the first, outer film metallization layer 106(1) in a fabrication process to support a higher density bump pitch. The package substrate 102 of the IC package 100 can support the first, bottom die 108(1) with a higher density of die connections. For example, the first, bottom die 108(1) may be a flip chip (FC) that has high density bump connections (e.g., FC ball-grid array (BGA) (FCBGA)). The softer material of the first, outer film metallization layer 106(1) can also better support compression bonding to the first, bottom die(s) 108(1).

Also, as discussed in more detail below, the package substrate 102 in the IC package 100 in FIG. 1A also includes a first PPG substrate 112(1) to better support wire bonding between a second, upper die 108(2) of the IC package 100 and the package substrate 102. A PPG substrate is a substrate that includes a reinforcing material, such as woven fiberglass or other fibers, impregnated in a resin matrix, such as an epoxy to provide a firmer, stronger and less flexible substrate. The combination of the resin and fibers can be partially cured or “pre-impregnated” before being used in a fabrication process. The second, upper die 108(2) is stacked on or adjacent to the first, bottom die 108(1) in the second, vertical direction (Z-axis direction). The second, upper die 108(2) may be directly coupled or bonded to the first, bottom die 108(1) as one example. As another example, the second, upper die 108(2) can be indirectly coupled to the first, bottom die 108(1) through an intermediate layer 109, such as an adhesive layer. Both the first, bottom die 108(1) and second, upper die 108(2) are surrounded by a mold layer 113. The first PPG substrate 112(1) includes a first PPG metallization layer 114(1) extending in the first, horizontal direction (X-axis and/or Y-axis direction(s)) and that is made from a stronger, PPG material, such as a dielectric material impregnated with fiberglass. Thus, the first PPG substrate 112(1) is better able to support wire bond connections to the second, upper die(s) 108(2) than the film substrate 104 since material properties of the flexible, softer material used to form the first, outer film metallization layer 106(1) may not support wire bonding techniques such as heat, pressure, and/or ultrasonic energy. The first PPG substrate 112(1) also reinforces the first, outer film metallization layer 106(1) of the film substrate 104 to reinforce and increase the strength of the film substrate 104 for increased stability of the package substrate 102 to reduce or minimize warpage. In this example, as discussed in more detail below, the first PPG metallization layer 114(1) of the first PPG substrate 112(1) is coupled to the first, outer film metallization layer 106(1) of the film substrate 104 in a second region 110(2) of the film substrate 104 outside of and laterally adjacent to the first, die region 110(1) of the film substrate 104 in the first, horizontal direction (X-axis and/or and Y-axis direction(s)). In this manner, the first, bottom die 108(1) has unobstructed access to be directly coupled to the first, outer film metallization layer 106(1) of the film substrate 104 to provide signal routing between the first, bottom die 108(1) and the package substrate 102. However, the first PPG substrate 112(1) supports metal pads that support wire bond connections through wire bonds 116(1), 116(2) between the first PPG substrate 112(1) and the film substrate 104, and the second, upper die 108(2) in the IC package 100.

In this manner, the package substrate 102 in FIG. 1A is a hybrid substrate in that it includes the film substrate 104 of the first, outer film metallization layer 106(1) (and/or other film metallization layers 106(2)-106(8) of softer material to support finer pitch metal interconnects for finer bump pitch for connection to the first, bottom die 108(1) in the first, die region 110(1). But, the inclusion of the first PPG substrate 112(1) on the film substrate 104 in the second region 110(2) can better support metal pads for forming the wire bond connections of the wire bonds 116(1), 116(2) while also providing strength and additional stability to the film substrate 104. In this example, the film substrate 104 also includes a core layer 117 that can provide strength and stability to the film substrate 104. However, the inclusion of the first PPG substrate 112(1) can provide additional strength and support to the film substrate 104.

FIG. 1B is a close-up, partial side view of the IC package 100 in FIG. 1A. With reference to FIG. 1B, each of the film metallization layers 106(1)-108(8) in this example, has a respective film insulating layer 118(1)-118(8) of a dielectric material (e.g., a plastic, polymer, ceramic) that has insulating properties and that is disposed on a surface as film in a fabrication process and then processed. By “film insulating layer,” it is meant that such layer is a sheet layer or coating of dielectric, insulating material disposed on a surface as a layer, which may then be processed to a desired thickness and with metallization. In this example, the film insulating layers 118(1)-118(8) are thinner layers of a first thickness shown by height H₁ in the second, vertical direction (Z-axis direction) orthogonal to the first, horizontal direction (X-axis and/or Y-axis direction(s)) and are made from a softer, material film, such as a polyimide. For example, the first thickness shown by the height H₁ of the film insulating layers 118(1)-118(8) may be between fifteen (15) and thirty (30) μm. As another example, the modulus of elasticity of the film insulating layers 118(1)-118(8) may be between five(5) GigaPascal (GPa) and twenty (20) GPa. For example, the film insulating layers 118(1)-118(8) may formed to fabricate the film substrate 104 as an additive process where each film insulating layer 118(1)-118(8) is formed and then processed to form its respective film metallization layers 106(1)-106(8), before another film insulating layer 118(1)-118(8) is deposited and processed on the last fabricated film metallization layer 106(1)-106(8).

With continuing reference to FIG. 1B, each of the film metallization layers 106(1)-106(8) in this example also includes a respective metal layer 120(1)-120(8) that is either disposed on or partially or fully embedded in a respective film insulating layer 118(1)-118(8). A metal layer is a layer that was a metal material that was then processed to form metal interconnects (e.g., metal traces, metal lines). Each of the metal layers 120(1)-120(8) has respective metal interconnects 122(1)-122(8) that is formed in the metal layer 120(1)-120(8) as a result of a fabricating and patterning process of the metal layers 120(1)-120(8) in this example. The metal interconnects 122(1)-122(8) are exposed from a respective first, outer surface 124(1)-124(8) of the film insulating layers 118(1)-118(8). In this example, first metal interconnects 122(1)(1) are exposed from the first, outer surface 124(1) of the first, outer film insulating layer 118(1) in the first, die region 110(1) of the film substrate 104 for coupling to the first, bottom die 108(1), as shown in FIG. 1A. This is also shown in the top view of the IC package 100 in FIG. 1E in reference to the side view of the IC package 100 in FIG. 1C. Also, in this example, as shown in FIG. 1A, first metal interconnects 122(1)(2) are exposed from the first, outer surface 124(1) of the first, outer film insulating layer 118(1) in the second region 110(2) of the film substrate 104 for coupling to the first PPG substrate 112(1). In this manner. die interconnects 123 of the first, bottom die 108(1) (shown in FIGS. 1A and 1B) can be coupled to the film substrate 104 for signal routing in the first, die region 110(1) unobstructed from the first PPG substrate 112(1) to support reduced bump pitch through a reduced first pitch PI of the metal interconnects 122(1)(1) in the first, die region 110(1). For example, the first pitch PI of the metal interconnects 122(1)(1) in the first, outer film metallization layer 106(1) in the first, die region 110(1) may be less than or equal to five (5) micrometers (μm).

With continuing reference to FIG. 1B, the first PPG metallization layer 114(1) is adjacent to the first surface 124(1) of the film metallization layer 106(1) of the film substrate 104. The first PPG metallization layer 114(1) in this example also includes a respective first metal layer 130(1) that is either disposed on or partially or fully embedded in a first PPG insulating layer 132(1). The first metal layer 130(1) has respective first metal pads 134(1) that are formed in the first metal layer 130(1) as a result of a fabricating and patterning process of the first metal layer 130(1) in this example. The first metal pads 134(1) are exposed from a respective first, outer surface 136(1) of the first PPG insulating layer 132(1) made from a PPG material. As an example, the modulus of elasticity of the first PPG insulating layer 132(1) may be between fourteen (14) and twenty-five (25) GigaPascal (GPa) and greater than the modulus of elasticity of the first, film insulating layer 118(1). In this example, the first PPG insulating layer 132(1) has a second thickness shown by height H₂ in the second, vertical direction (Z-axis direction).

The first PPG insulating layer 132(1) can have a second thickness H₂ between fifteen (15) and forty-five (45) μm. A ratio of the second thickness H₂ of the first PPG insulating layer 132(1) to the first thickness H₁ of the first, outer film insulating layer 118(1) can be at least 1.5.

As shown in FIG. 1B, in this example, the first metal pads 134(1) are exposed from the first, outer surface 136(1) of the first PPG metallization layer 114(1) in the second region 110(2) of the film substrate 104 to support the ability to couple the first metal pads 134(1) to a wire bond 116(1), 116(2) to be coupled to the second, upper die 108(2). This is shown in the top view of the IC package 100 in FIG. 1D in reference to the side view of the IC package 100 in FIG. 1C. In this manner, the second, upper die 108(2) can be coupled to the first PPG substrate 112(1), which in turn is coupled to the film substrate 104 for signal routing in the second region 110(2) unobstructed from the first, bottom die 108(1). A second pitch P₂ of the first metal pads 134(1) in the first PPG metallization layer 114(1) may be able to be relaxed versus the pitch of the metal interconnects 122(1) in the first, outer film metallization layer 106(1) since the number of wire bonds 116(1), 116(2) may not require reduced pitch connections. For example, the second pitch P₂ of the first metal pads 134(1) in the first PPG metallization layer 114(1) may be one hundred fifty (150) μm. The first metal pads 134(1) are exposed from a first solder resist layer 139(1) that is disposed on the first PPG substrate 112(1) and patterned with first openings 141(1) during fabrication of the IC package 100.

Note that although the example above is discussed with regard to a reduced first pitch P₁ of the metal interconnects 122(1)(1) in the first, outer film metallization layer 106(1) in the first, die region 110(1), the metal interconnects 122(1)(2) in the first, outer film metallization layer 106(1) in the second region 110(2) can also be formed at the reduced first pitch P₁. The metal interconnects 122(2)-122(8) in the other film metallization layers 106(2)-106(8) can also be formed at the reduced first pitch PI or second pitch P₂ as desired, as other examples. Also note that although the first PPG substrate 112(1) in the IC package 100 only includes one PPG metallization layer, the first PPG substrate 112(1) could be provided with multiple stacked PPG metallization layers.

As shown in FIG. 1B, to provide a signal routing path between the wire bonds 116(1), 116(2) coupled to the first metal pads 134(1) of the first PPG substrate 112(1) and the film substrate 104, the first PPG metallization layer 114(1) has first vias 138(1) that couple the first metal pads 134(1) to the first metal interconnects 122(1) of the first, outer film metallization layer 106(1). In this manner, vias 140(1) in the first, outer film metallization layer 106(1) and coupled to the metal interconnects 122(1) can extend the signal routing path from the first PPG substrate 112(1) to the other film metallization layers 106(2)-106(8) of the film substrate 104 through vias 140(2)-140(8) to interconnect metal interconnects 122(2)-122(8) in adjacent film metallization layers 106(2)-106(8). In this example, the core layer 117 includes metal pillars 144 that extend from the fourth film metallization layer 106(4) to the fifth film metallization layer 106(5) to provide signal routing paths between coupled metal interconnects 122(4), 122(5) in these layers. These signal routing paths can provide die-to-die (D2D) connections from the second, upper die 108(2) to the first, bottom die 108(1) through connections through the first PPG substrate 112(1) and the film substrate 104. These signal routing paths can also provide an external routing path for the second, upper die 108(2) and the first, bottom die 108(1) to external interconnects 142 of the IC package 100.

Further, as also shown in FIGS. 1A and 1B, in this example, a second PPG substrate 112(2) may also be included in the package substrate 102 and coupled to the film metallization layer 106(8) of the film substrate 104 to further reinforce the film substrate 104 and the package substrate 102. The second PPG substrate 112(2) has a second PPG metallization layer 114(2) that has a second PPG insulating layer 132(2) that has second vias 138(2) that couple second metal pads 134(2) to the metal interconnects 122(8) of the film metallization layer 106(8). In this manner, vias 140(8) in the film metallization layer 106(8) and coupled to the metal interconnects 122(8) can extend the signal routing path from the first PPG substrate 112(1) and the film substrate 104 to the second PPG metallization layer 114(2) and to the external interconnects 142. A second solder resist layer 139(2) is disposed on the second PPG metallization layer 114(2) with second openings 141(2) formed therein to expose the second metal pads 134(2) and couple the second metal pads 134(2) to the external interconnects 142.

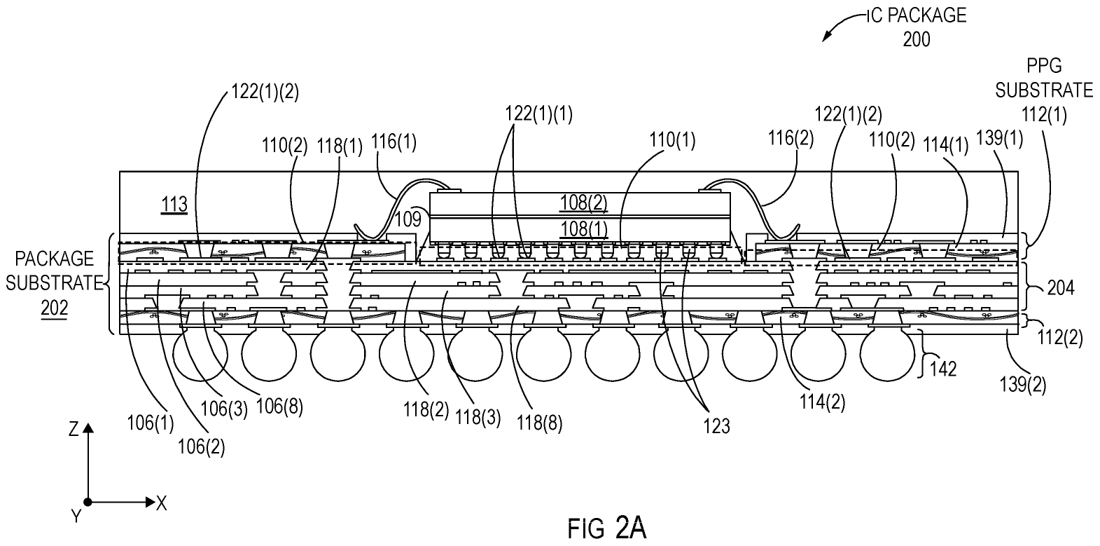

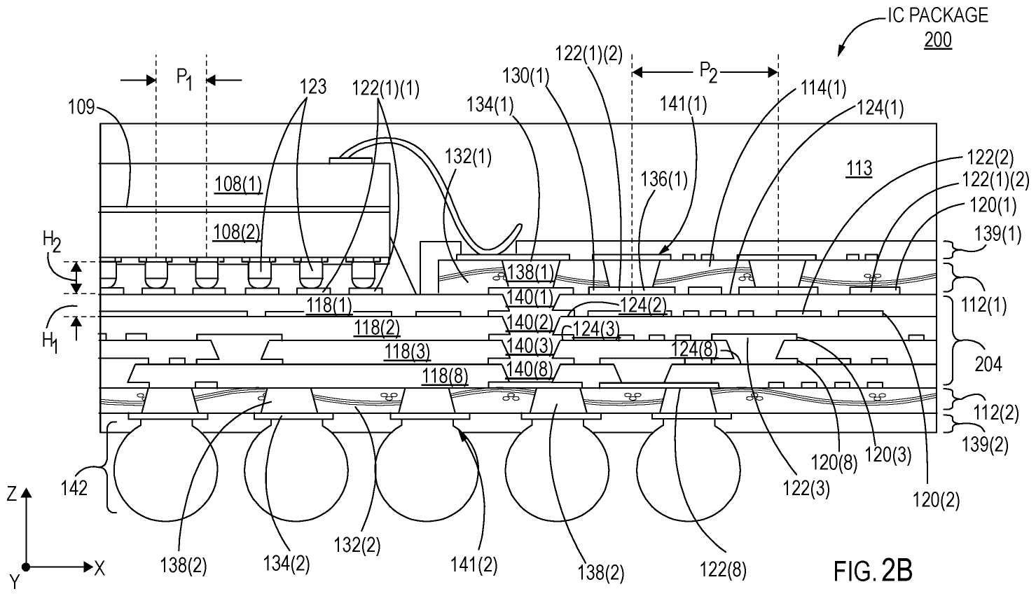

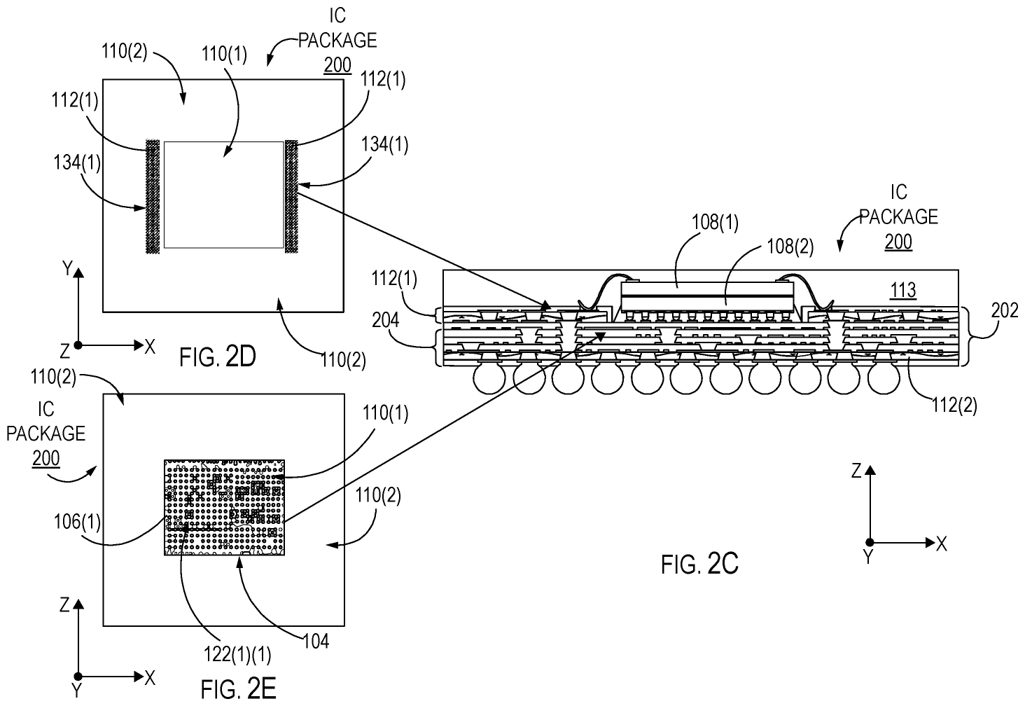

FIGS. 2A and 2B are a side view and close-up, partial side view, respectively, of an exemplary hybrid IC package 200 (referred to as “IC package 200”) that is similar to the IC package in 100 in FIGS. 1A-1E, except the film substrate 104 is a coreless substrate. Common elements between the package substrate 202 in FIGS. 2A and 2B and the package substrate 100 in FIGS. 1A-1E are shown with common element numbers, and are not re-described.

In this regard, FIGS. 2A and 2B are a side view and close-up, partial side view, respectively, of an exemplary hybrid IC package 200 (also referred to as “IC package 200”) that includes a package substrate 202 that includes a first, film substrate 204. In this example, the film substrate 204 is coreless. The film substrate 204 is a substrate that is formed from one or more film insulating layers built upon each other to form respective metallization layers in a fabrication process. The film insulating layers may have a reduced height or thickness available through an additive fabrication process, as opposed to other types of insulating layers used in package substrates, such as a laminated substrate that includes separately formed insulating layers that are then laminated together. The film substrate 204 of the package substrate 202 includes the film metallization layers 106(1)-106(3), 106(8) to support higher density bump pitch for a die connection to the first, bottom die 108(1) in the first, die region 110(1) of the film substrate 204.

Also, the package substrate 202 in the IC package 200 in FIG. 2A includes a first PPG substrate 112(1) to better support wire bonding between a second, upper die 108(2) of the IC package 200 and the package substrate 202. The first PPG metallization layer 114(1) of the first PPG substrate 112(1) is coupled to the first, outer film metallization layer 106(1) of the film substrate 204 in the second region 110(2) of the film substrate 204 outside of and laterally adjacent to the first, die region 110(1) of the film substrate 204 in a first, horizontal direction (X-axis and/or and Y-axis direction(s)). In this manner, the first, bottom die 108(1) has unobstructed access to be directly coupled to the first, outer film metallization layer 106(1) of the film substrate 204 to provide signal routing between the first, bottom die 108(1) and the package substrate 202.

FIG. 2B is a close-up, partial side view of the IC package 200 in FIG. 2A. As shown in FIG. 2B, the metal layers 120(1)-120(3), 120(8) are either disposed on or partially or fully embedded in respective film insulating layers 118(1)-118(3), 118(8). Each of the metal layers 120(1)-120(3), 120(8) has a respective metal interconnect 122(1)-124(3), 122(8) that is formed in the metal layer 120(1)-120(3), 120(8) as a result of a fabricating and patterning process of the metal layers 120(1)-120(3), 120(8) in this example. This is also shown in the top view of the IC package 200 in FIG. 2E in reference to the side view of the IC package 200 in FIG. 2C. Also, in this example, as shown in FIG. 2A, first metal interconnects 122(1)(2) are exposed from the first, outer surface 124(1) of the first, outer film insulating layer 118(1) in the second region 110(2) of the film substrate 204 for coupling to the first PPG substrate 112(1). In this manner, die interconnects 123 of the first, bottom die 108(1) (shown in FIGS. 2A and 2B) can be coupled to the film substrate 204 for signal routing in the first, die region 110(1) unobstructed from the first PPG substrate 112(1) to support reduced bump pitch through a reduced first pitch PI of the metal interconnects 122(1)(1) in the first, die region 110(1).

As shown in FIG. 2B, in this example, metal pads 134(1) are exposed from the first, outer surface 136(1) of the first PPG metallization layer 114(1) in the second region 110(2) of the film substrate 204 to support the ability to couple the metal pads 134(1) to a wire bond 116(1), 116(2) to be coupled to the second, upper die 108(2). This is shown in the top view of the IC package 200 in FIG. 2D in reference to the side view of the IC package 200 in FIG. 2C. In this manner, the second, upper die 108(2) can be coupled to the first PPG substrate 112(1), which in turn is coupled to the film substrate 204 for signal routing in the second region 110(2) unobstructed from the first, bottom die 108(1). The second pitch P₂ of the metal pads 134(1) in the first PPG metallization layer 114(1) may be able to be relaxed versus the pitch of the metal interconnects 122(1) in the first, outer film metallization layer 106(1) since the number of wire bonds 116(1), 116(2) may not require reduced pitch connections.

Note that although the example above is discussed with regard to a reduced first pitch P₁ of the metal interconnects 122(1)(1) in the first, outer film metallization layer 106(1) in the first, die region 110(1), the metal interconnects 122(1)(2) in the first, outer film metallization layer 106(1) in the second die region 110(2) can also be formed of at the reduced first pitch P₁. The metal interconnects 122(2), 122(3), 122(8) in the other film metallization layers 106(2), 106(3), 106(8) can also be formed of the reduced first pitch P₁ or second pitch P₂ as desired, as other examples. Also note that although the first PPG substrate 112(1) in the IC package 200 only includes one PPG metallization layer, the first PPG substrate 112(1) could be provided with multiple stacked PPG metallization layers.

As shown in FIG. 2B, to provide a signal routing path between the wire bonds 116(1), 116(2) coupled to the metal pads 134(1) of the first PPG substrate 112(1) and the film substrate 204, the first PPG metallization layer 114(1) has first vias 138(1) that couple the metal pads 134(1) to the first metal interconnects 122(1) of the first, outer film metallization layer 106(1). In this manner, vias 140(1) in the first, outer film metallization layer 106(1) and coupled to the metal interconnects 122(1) can extend the signal routing path from the first PPG substrate 112(1) to the other film metallization layers 106(2)-106(3), 106(8) of the film substrate 204 through vias 140(2)-140(4) interconnecting metal interconnects 122(2)-122(3), 122(8) in adjacent film metallization layers 106(2)-106(3), 106(8). These signal routing paths can provide die-to-die (D2D) connections from the second, upper die 108(2) to the first, bottom die 108(1) through connections through the first PPG substrate 112(1) and the film substrate 204. These signal routing paths can also provide an external routing path for the second, upper die 108(2) and the first, bottom die 108(1) to the external interconnects 142 of the IC package 100.

Further, as also shown in FIGS. 2A and 2B, in this example, the second PPG substrate 112(2) can also be included in the package substrate 202 and coupled to the film metallization layer 106(8) of the film substrate 204 to further reinforce the film substrate 204 and the package substrate 202. The second PPG substrate 112(2) has a second PPG metallization layer 114(2) that has a second PPG insulating layer 132(2) that has second vias 138(2) that couple the second metal pads 134(2) to the metal interconnects 122(8) of the film metallization layer 106(8). In this manner, vias 140(8) in the film metallization layer 106(8) and coupled to the metal interconnects 122(8) can extend the signal routing path from the first PPG substrate 112(1) and the film substrate 204 to the second PPG metallization layer 114(2) and to the external interconnects 142. The second solder resist layer 139(2) is disposed on the second PPG metallization layer 114(2) with second openings 141(2) formed therein to expose the second metal pads 134(2) and couple the second metal pads 134(2) to the external interconnects 142.

A package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E and 2A-2E, can be fabricated in different fabrication processes.

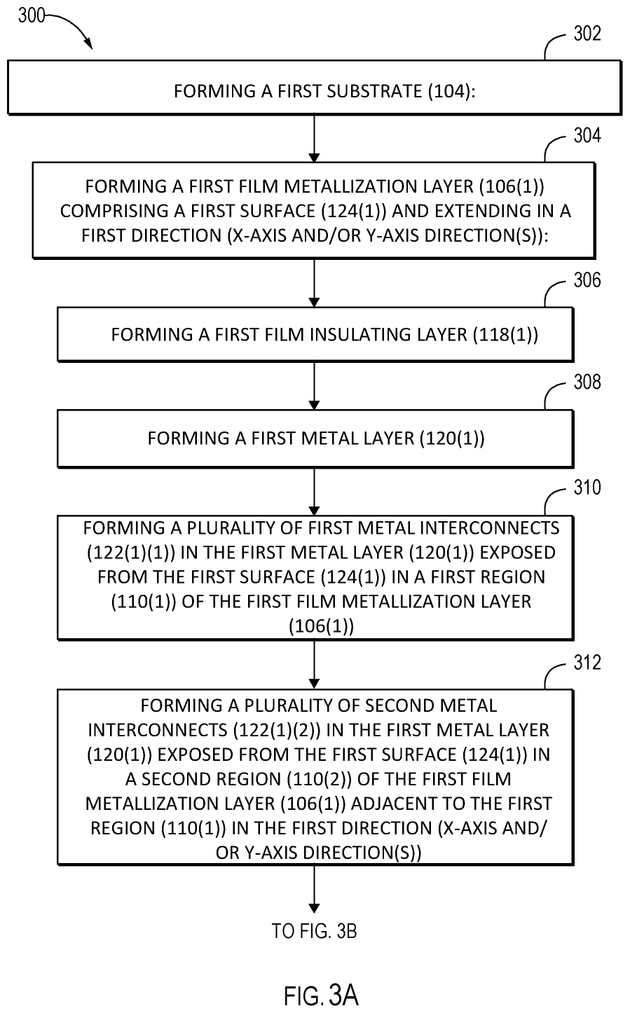

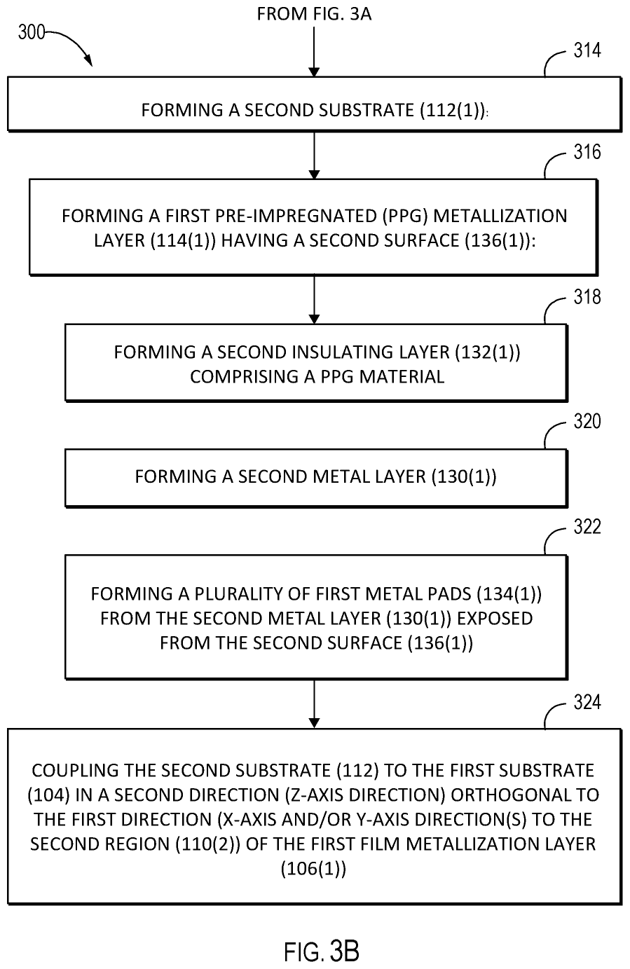

In this regard, FIGS. 3A and 3B is a flowchart illustrating an exemplary fabrication process 300 of fabricating a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E and 2A-2E. The fabrication process 300 in FIGS. 3A and 3B will now be discussed in conjunction with fabricating the package substrate 102 in FIGS. 1A-1E, but note that such is not limiting. The fabrication process 300 in FIGS. 3A and 3B can be used to fabricate other package substrates that include a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrate 202 in FIGS. 2A-2E.

In this regard, a first step in the fabrication process 300 in fabricating the package substrate 102 includes forming a first substrate 104 (block 302 in FIG. 3A). Forming the first substrate 104 includes forming a first film metallization layer 106(1) comprising a first surface 124(1) and extending in a first direction (X-axis and/or Y-axis direction(s)) (block 304 in FIG. 3A). Forming the first film metallization layer 106(1)) includes forming a first film insulating layer 118(1) (block 306 in FIG. 3A), forming a first metal layer 120(1) (block 308 in FIG. 3A), forming a plurality of first metal interconnects 122(1)(1) in the first metal layer 120(1) exposed from the first surface 124(1) in a first region 110(1) of the first film metallization layer 106(1) (block 310 in FIG. 3A), and forming a plurality of second metal interconnects 122(1)(2) in the first metal layer 120(1) exposed from the first surface 124(1) in a second region 110(2) of the first film metallization layer 106(1) adjacent to the first region 110(1) in the first direction (X-axis and/or Y-axis direction(s)) (block 312 in FIG. 3A).

With reference to FIG. 3B, forming the package substrate 102 in the fabrication process 300 also includes forming a second substrate 112(1) (block 314 in FIG. 3B). Forming the second substrate 112(1) includes forming a first PPG metallization layer 114(1) having a second surface 136(1) (block 316 in FIG. 3B). Forming the first PPG metallization layer 114(1) includes forming a second insulating layer 132(1) comprising a PPG material (block 318 in FIG. 3B), forming a second metal layer 130(1) (block 320 in FIG. 3B), and forming a plurality of first metal pads 134(1) from the second metal layer 130(1) exposed from the second surface 136(1) (block 322 in FIG. 3B). Forming the package substrate 102 also includes coupling the second substrate 112(1) to the first substrate 104 in a second direction (Z-axis direction) orthogonal to the first direction (X-axis and/or Y-axis direction(s) in the second region 110(2) of the first film metallization layer 106(1) (block 324 in FIG. 3B).

Other fabrication processes can also be employed to fabricate a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E and 2A-2E.

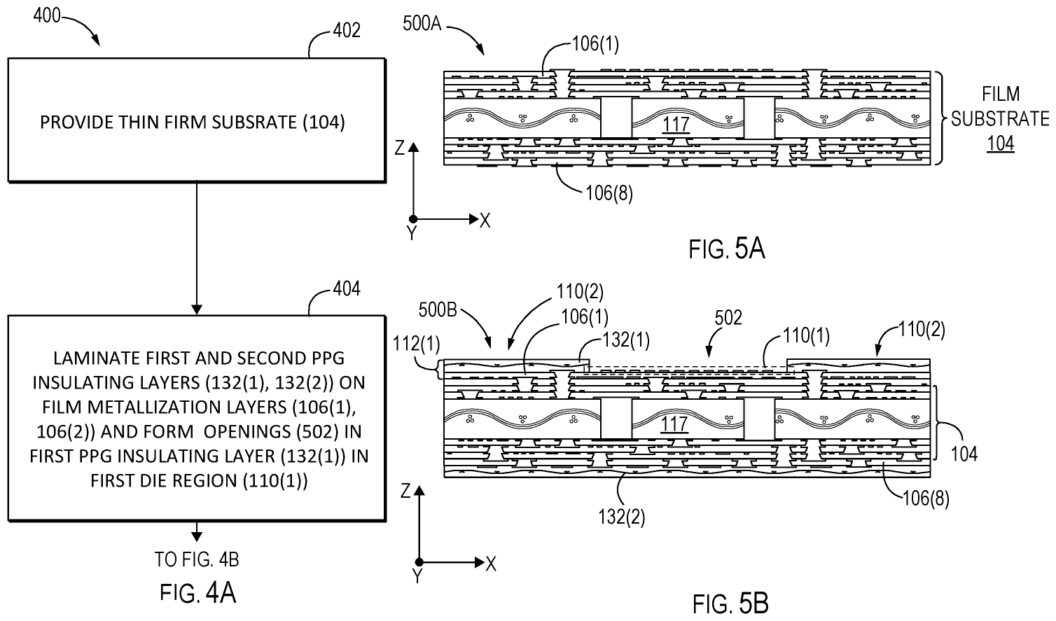

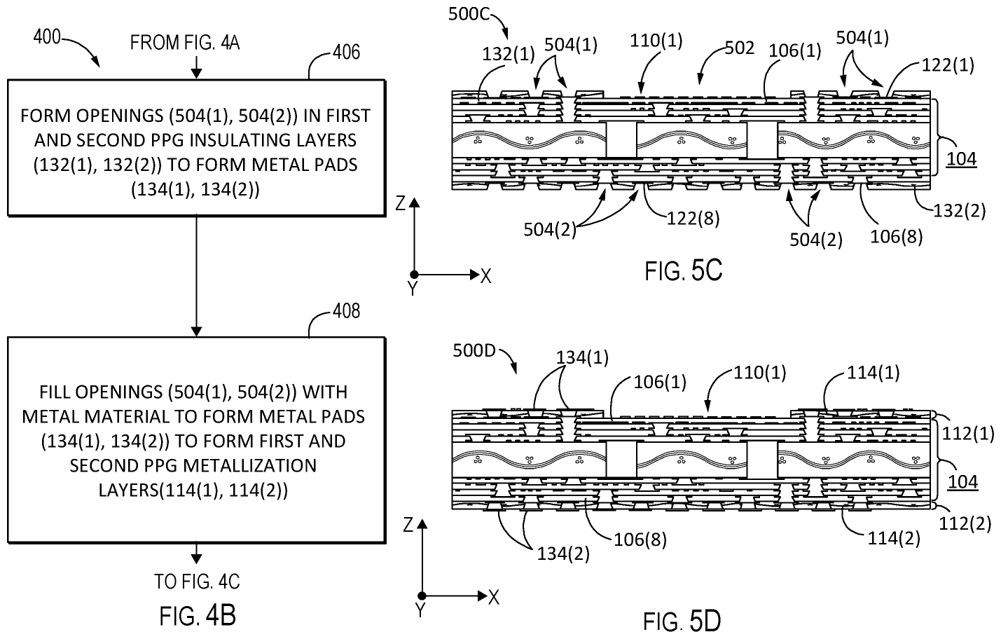

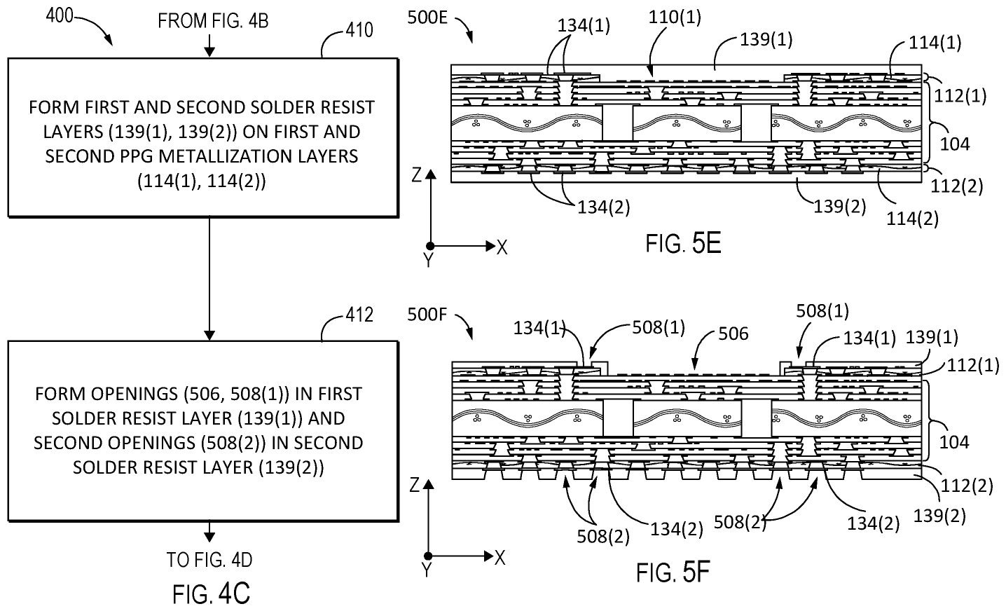

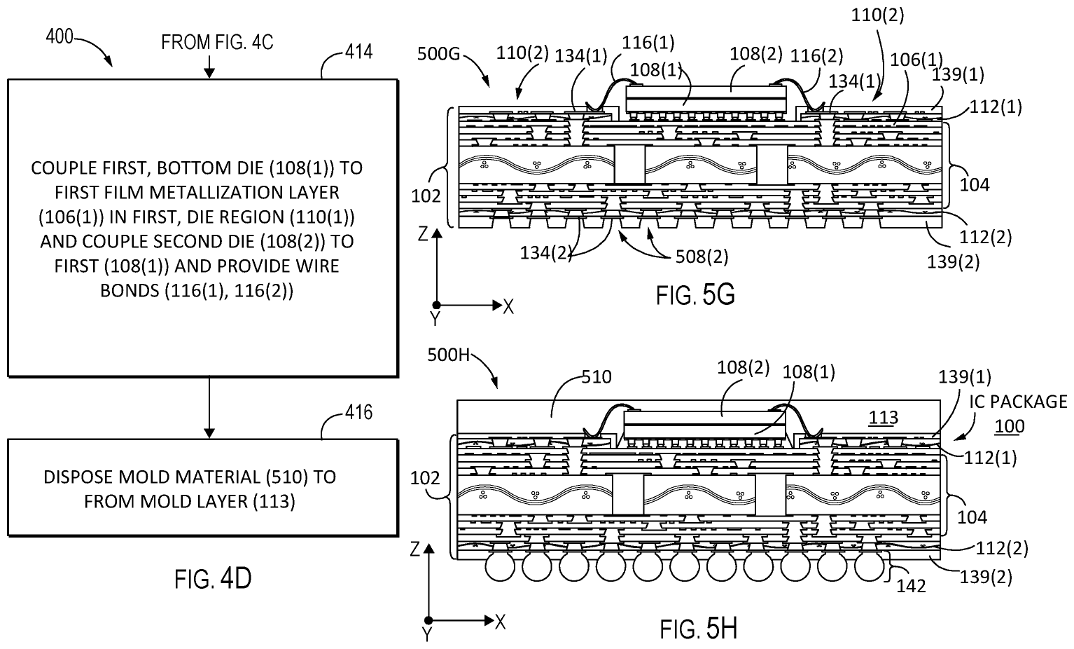

In this regard, FIGS. 4A-4D is a flowchart illustrating another exemplary fabrication process 400 of fabricating a cored package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrate 102 and associated IC package 100 in FIGS. 1A-1E. FIGS. 5A-5H are exemplary fabrication stages 500A-500H during fabrication of the package substrate according to the fabrication process 400 in FIGS. 4A-4D. The fabrication process 400 as shown in the fabrication stages 500A-500H in FIGS. 5A-5H are discussed in reference to the cored package substrate 102 in FIGS. 1A-1E. However, note that the fabrication process 400 could be employed to fabricate another cored package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package.

In this regard, as shown the fabrication stage 500A in FIG. 5A, a first exemplary step in the fabrication process 400 is to provide the film substrate 104 (block 402 in FIG. 4A). As previously discussed with regard to FIGS. 1A and 1B, the film substrate 104 includes the film metallization layers 106(1)-106(8) with the core layer 117 disposed therebetween. The film substrate 104 can be formed by forming the film metallization layers 106(1)-106(8) one layer at a time as part of an additive process (e.g., a semi-additive process (SAP). The film substrate 104 could also be formed as an embedded trace substrate (ETS). Then, as shown in the fabrication stage 500B in FIG. 5B, a next exemplary step in the fabrication process 400 is to laminate the first and second PPG insulating layers 132(1), 132(2) on the respective first, outer film metallization layer 106(1) and film metallization layer 106(8) of the film substrate 104 (block 404 in FIG. 4A). An opening 502 is formed in the first PPG insulating layer 132(1) to provide the first, die region 110(1) to provide an unobstructed access to the film substrate 104 and its first, outer film metallization layer 106(1) to be able to couple the first, bottom die 108(1) (see FIGS. 1A and 1B) to the film substrate 104. The opening 502 may be pre-punched in the first PPG insulating layer 132(1) before being disposed on the first, outer film metallization layer 106(1) as a laminated layer. Alternatively, the opening 502 may be formed in the first PPG insulating layer 132(1) after being laminated onto the first, outer film metallization layer 106(1).

Then, as shown in the fabrication stage 500C in FIG. 5C, a next exemplary step in the fabrication process 400 is to form the first and second PPG metallization layers 114(1), 114(2) for the first and second PPG substrates 112(1), 112(2) by forming openings 504(1), 504(2) in the first and second PPG insulating layers 132(1), 132(2) down to the metal interconnects 122(1), 122(8) of the film metallization layers 106(1), 106(8) of the film substrate 104 (block 406 in FIG. 4B). For example, the openings 504(1), 504(2) may be formed by a drilling process by drilling the openings 504(1), 504(2) into the respective first and second PPG insulating layers 132(1), 132(2). Alternatively, a patterning and lithography process could be employed to form the openings 504(1), 504(2). This is to be able to fill in the openings 504(1), 504(2) with a metal material, such as through a metal plating process, to form the first and second metal pads 134(1), 134(2) in the respective first and second PPG insulating layers 132(1), 132(2) to form the first and second PPG metallization layers 114(1), 114(2) as part of the first and second PPG substrates 112(1), 112(2), as shown in the fabrication stage 500D in FIG. 5D (block 408 in FIG. 4B). The metal pads 134(1), 134(2) could be formed by forming a metal layer on the first and second PPG insulating layers 132(1), 132(2) and using a lithography process to form openings to dispose metal material in the openings 504(1), 504(2).

Then, as shown in the fabrication stage 500E in FIG. 5E, a next exemplary step in the fabrication process 400 is to form the first and second solder resist layers 139(1), 139(2) on the respective first and second PPG metallization layers 114(1), 114(2) (block 410 in FIG. 4C). Then, as shown in the fabrication stage 500F in FIG. 5F, the first and second solder resist layers 139(1), 139(2) are processed to form an opening 506 in the first, die region 110(1) to provide access for bonding the bottom, first die 108(1) to the film substrate 104 (block 412 in FIG. 4C). First and second openings 508(1), 508(2) are also formed in the first and second solder resist layers 139(1), 139(2) to expose the certain first and second metal pads 134(1), 134(2) for respective wire bond 116(1), 116(2) and external interconnect 142 connections (block 412 in FIG. 4C).

Then, as shown in the fabrication stage 500G in FIG. 5G, a next exemplary step in the fabrication process 400 is to couple the first, bottom die 108(1) to the first, outer film metallization layer 106(1) of the film substrate 104 in the first, die region 110(1) (block 414 in FIG. 4D). The second, upper die 108(2) is bonded or otherwise coupled to the first, bottom die 108(2) (block 414 in FIG. 4D). Wire bonds 116(1), 116(2) are used to couple the second die 108(2) to first metal pads 134(1) in the first PPG substrate 112(1). Then, as shown in the fabrication stage 500G in FIG. 5G, a next exemplary step in the fabrication process 400 is to dispose a mold material 510 on the first and second dies 108(1), 108(2) and the first solder resist layer 139(1) to form the mold layer 113 over the first and second dies 108(1), 108(2) and the first solder resist layer 139(1) to form the IC package 100 (block 416 in FIG. 4D).

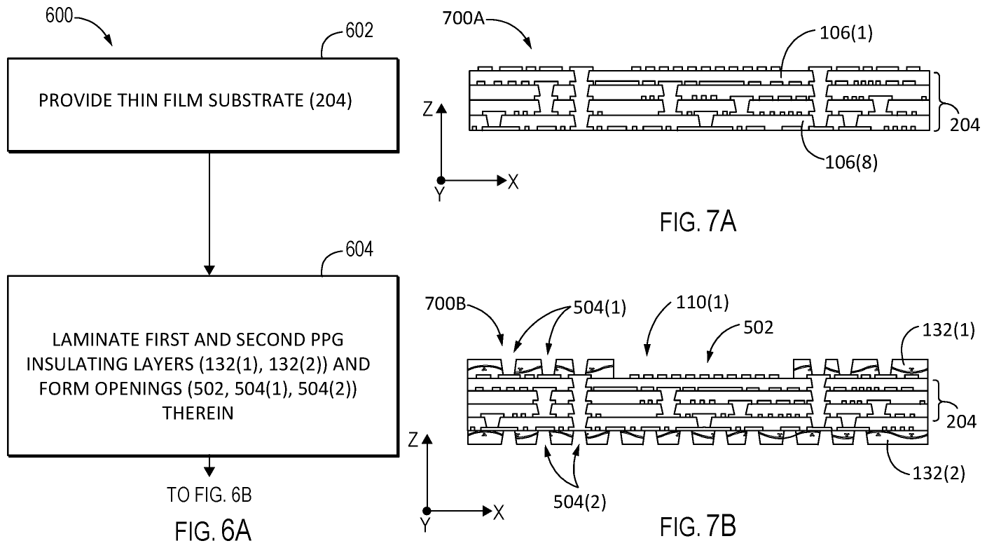

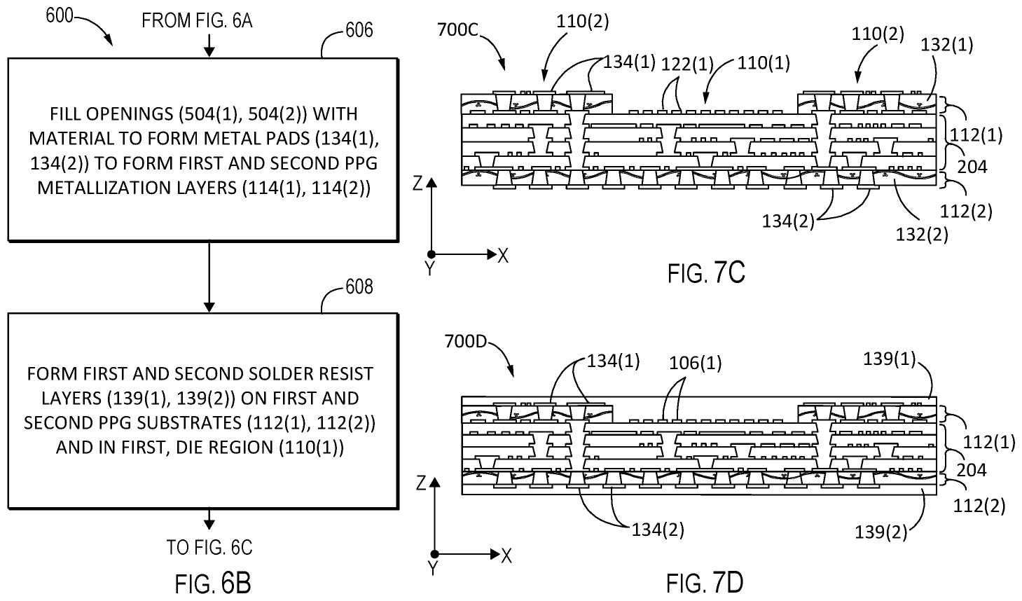

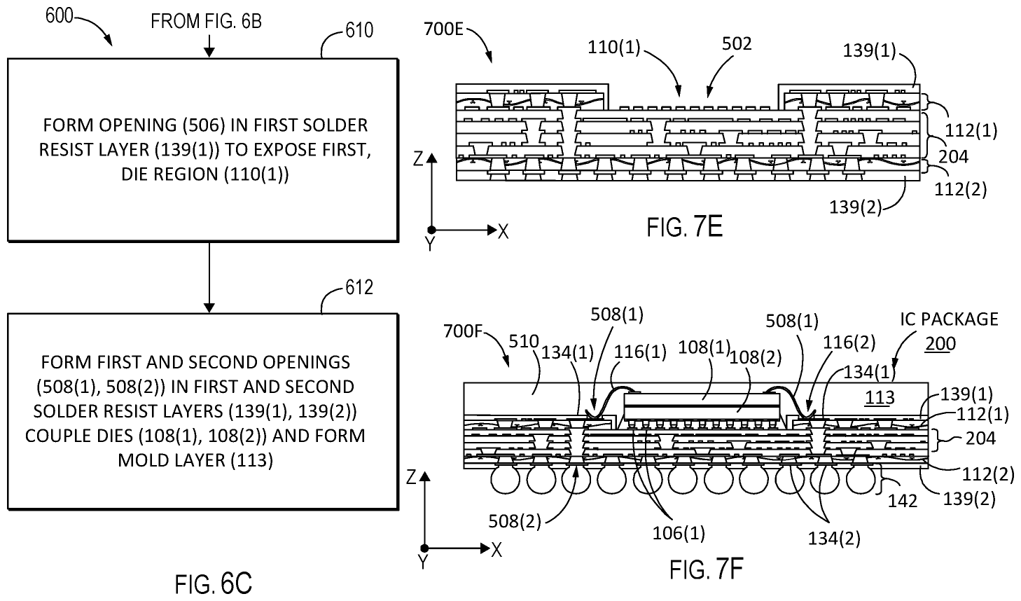

FIGS. 6A-6C is a flowchart illustrating another exemplary fabrication process 600 of fabricating a coreless package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrate 202 and associated IC package 200 in FIGS. 2A-2E. FIGS. 7A-7F are exemplary fabrication stages 700A-700F during fabrication of the package substrate according to the fabrication process 600 in FIGS. 6A-6C. The fabrication process 600 as shown in the fabrication stages 700A-700F in FIGS. 7A-7F are discussed in reference to the coreless package substrate 202 in FIGS. 2A-2E. However, note that the fabrication process 600 could be employed to fabricate another coreless package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package.

In this regard, as shown the fabrication stage 700A in FIG. 7A, a first exemplary step in the fabrication process 600 is to provide the film substrate 204 (block 602 in FIG. 6A). As previously discussed with regard to FIGS. 2A and 2B, the film substrate 204 includes the film metallization layers 106(1)-106(3), 106(8) without a core layer. The film substrate 204 can be formed by forming the film metallization layers 106(1)-106(3), 106(8) one layer at a time as part of an additive process (e.g., a semi-additive process (SAP). The film substrate 204 could also be formed as an embedded trace substrate (ETS). Then, as shown in the fabrication stage 700B in FIG. 7B, a next exemplary step in the fabrication process 400 is to laminate the first and second PPG insulating layers 132(1), 132(2) on the respective first, outer film metallization layer 106(1) and film metallization layer 106(8) of the film substrate 204 (block 604 in FIG. 6A). An opening 502 is formed in the first PPG insulating layer 132(1) to provide the first, die region 110(1) to provide unobstructed access to the film substrate 104 and its first, outer film metallization layer 106(1) to be able to couple the first, bottom die 108(1) (see FIGS. 2A and 2B) to the film substrate 204. The opening 502 may be pre-punched in the first PPG insulating layer 132(1) before being disposed on the first, outer film metallization layer 106(1) as a laminated layer. Alternatively, the opening 502 may be formed in the first PPG insulating layer 132(1) after being laminated onto the first, outer film metallization layer 106(1).

As also shown in the fabrication stage 700B in FIG. 7B, the first, and second PPG metallization layers 114(1), 114(2) are formed for the first and second PPG substrates 112(1), 112(2) by forming openings 504(1), 504(2) in the first and second PPG insulating layers 132(1), 132(2) down to the metal interconnects 122(1), 122(8) of the film metallization layers 106(1), 106(8) of the film substrate 104 (block 604 in FIG. 6A). For example, the openings 504(1), 504(2) may be formed by a drilling process by drilling the openings 504(1), 504(2) into the respective first and second PPG insulating layers 132(1), 132(2). Alternatively, a patterning and lithography process could be employed to form the openings 504(1), 504(2). This is to be able to fill in the openings 504(1), 504(2) with a metal material, such as through a metal plating process, to form the first and second metal pads 134(1), 134(2) in the respective first and second PPG insulating layers 132(1), 132(2) to form the first and second PPG metallization layers 114(1), 114(2) as part of the first and second PPG substrates 112(1), 112(2), as shown in the shown in the fabrication stage 700C in FIG. 7C (block 606 in FIG. 6B). The metal pads 134(1), 134(2) could be formed by forming a metal layer on the first and second PPG insulating layers 132(1), 132(2) and using a lithography process to form openings to dispose metal material in the openings 504(1), 504(2).

Then, as shown in the fabrication stage 700D in FIG. 7D, a next exemplary step in the fabrication process 600 is to form the first and second solder resist layers 139(1), 139(2) on the respective first and second PPG metallization layers 114(1), 114(2) (block 608 in FIG. 6B). Then, as shown in the fabrication stage 700E in FIG. 7E, the first and second solder resist layers 139(1), 139(2) are processed to form an opening 506(1) in the first, die region 110(1) to provide access for bonding the bottom, first die 108(1) to the film substrate 104 (block 610 in FIG. 6C). First and second openings 508(1), 508(2) are also formed in the first and second solder resist layers 139(1), 139(2) to expose the certain first and second metal pads 134(1), 134(2) for respective wire bond 116(1), 116(2) and external interconnect 142 connections (block 612 in FIG. 6C).

The first, bottom die 108(1) is coupled the first, outer film metallization layer 106(1) of the film substrate 104 in the first, die region 110(1) (block 612 in FIG. 6C). The second, upper die 108(2) is bonded or otherwise coupled to the first, bottom die 108(1) (block 612 in FIG. 6C). Wire bonds 116(1), 116(2) are used to couple the second die 108(2) to first metal pads 134(1) in the first PPG substrate 112(1). Then, a mold material 510 is disposed on the first and second dies 108(1), 108(2) and the first solder resist layer 139(1) to form the mold layer 113 over the first and second dies 108(1), 108(2) and the first solder resist layer 139(1) to form the IC package 200 (block 612 in FIG. 6C).

Note that the terms “upper” and “top” where used herein are relative terms and are not meant to limit or imply a strict orientation that a “top” referenced element must always be oriented to be above a “bottom” referenced element, and vice versa. Note that the terms “lower” and “bottom” where used herein are relative terms and are not meant to limit or imply a strict orientation that a “bottom” or “lower” referenced element must always be oriented to be below a “top” or “upper” referenced element, and vice versa. Also, note that the terms “above” and “below” where used herein are relative terms and are not meant to limit or imply a strict orientation that an element referenced as being “above” another referenced element must always be oriented to be above the other referenced element with respect to ground, or that an element referenced as being “below” another referenced element must always be oriented to be below the other referenced element with respect to ground.

An object being “adjacent” as discussed herein relates to an object being beside or next to another stated object. Adjacent objects may not be directly physically coupled to each other. An object can be directly adjacent to another object which means that such objects are directly beside or next to the other object without another object or layer being intervening or disposed between the directly adjacent objects. An object can be indirectly or non-directly adjacent to another object which means that such objects are not directly beside or directly next to each other, but there is an intervening object or layer disposed between the non-directly adjacent objects.

A package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E, 2A-2E, 5G and 5H, and 7E and 7F, and that can be fabricated according to the exemplary fabrication processes in FIGS. 3A-3B. 4A-4D, and 6A-6C, and according to any aspects disclosed herein, may be provided in an IC package provided in or integrated into any processor-based device. Examples, without limitation, include a set top box, an entertainment unit, a navigation device, a communications device, a fixed location data unit, a mobile location data unit, a global positioning system (GPS) device, a mobile phone, a cellular phone, a smart phone, a session initiation protocol (SIP) phone, a tablet, a phablet, a server, a computer, a portable computer, a mobile computing device, a wearable computing device (e.g., a smart watch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, an avionics system, a drone, and a multicopter.

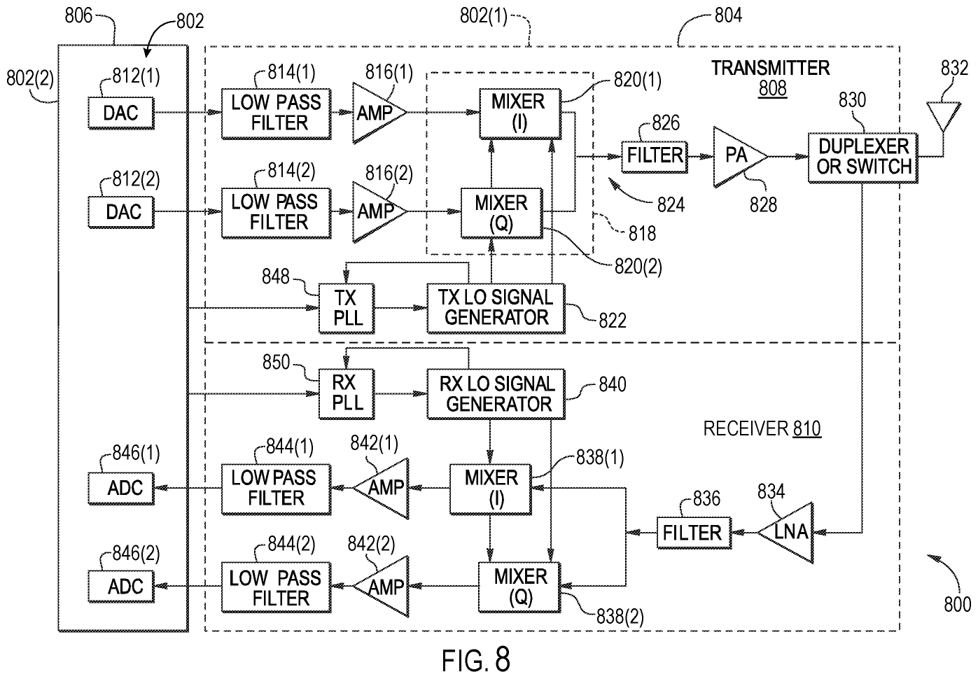

In this regard, FIG. 8 illustrates an exemplary wireless communications device 800 that includes radio frequency (RF) components formed from one or more IC packages 802(1), 802(2), wherein any of the IC packages 802(1), 802(2) includes a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E, 2A-2E, 5G and 5H, and 7E and 7F, and that can be fabricated according to the exemplary fabrication processes in FIGS. 3A-3B, 4A-4D, and 6A-6C, and according to any aspects disclosed herein. The wireless communications device 800 may include or be provided in any of the above-referenced devices, as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RF ICs (RFICs), mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage, and then from IF to baseband in another stage for the receiver 810. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals through mixers 820(1), 820(2) from a TX LO signal generator 822 to provide an upconverted signal 824. A filter 826 filters the upconverted signal 824 to remove undesired signals caused by the frequency up-conversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Down-conversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency up-conversion, while the RX LO signal generator 840 generates the I and Q RX LO signals used for frequency down-conversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

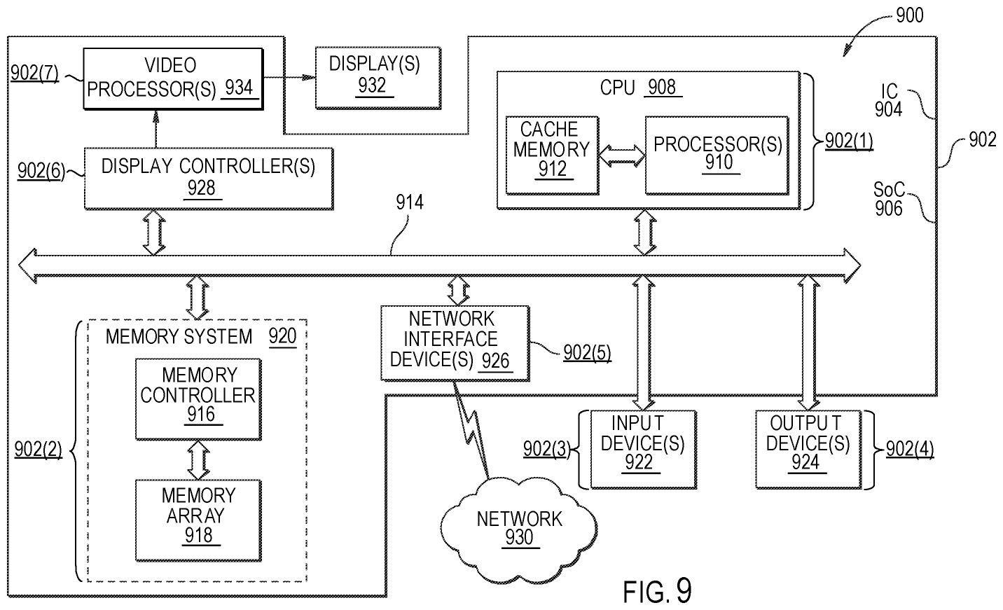

FIG. 9 illustrates an example of a processor-based system 900 that includes circuits that can be provided in an IC package(s) 902. 902(1)-902(7) that includes a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E, 2A-2E, 5G and 5H, and 7E and 7F, and that can be fabricated according to the exemplary fabrication processes in FIGS. 3A-3B, 4A-4D, and 6A-6C, and according to any aspects disclosed herein. Any of the IC packages 902, 902(1)-902(6) can include a package substrate that includes a film substrate with one or more film metallization layers to support higher density bump pitch for die connections to a first, bottom die(s) in a first, die region in the film substrate, and a PPG substrate of one or more PPG metallization layers in a second region of the film substrate outside the die region, to reinforce the film substrate and support wire bond connections to a second, upper die(s) in the hybrid IC package, including, but not limited to, the package substrates and associated IC packages in FIGS. 1A-1E, 2A-2E, 5G and 5H, and 7E and 7F, and that can be fabricated according to the exemplary fabrication processes in FIGS. 3A-3B, 4A-4D, and 6A-6C, and according to any aspects disclosed herein.

In this example, the processor-based system 900 may be formed as an IC 904 in an IC package 902 and as a system-on-a-chip (SoC) 906. The processor-based system 900 includes a central processing unit (CPU) 908 that includes one or more processors 910, which may also be referred to as CPU cores or processor cores. The CPU 908 can be included in an IC package 902(1). The CPU 908 may have cache memory 912 coupled to the CPU 908 for rapid access to temporarily stored data. The CPU 908 is coupled to a system bus 914 and can intercouple master and slave devices included in the processor-based system 900. As is well known, the CPU 908 communicates with these other devices by exchanging address, control, and data information over the system bus 914. For example, the CPU 908 can communicate bus transaction requests to a memory controller 916, as an example of a slave device. Although not illustrated in FIG. 9, multiple system buses 914 could be provided, wherein each system bus 914 constitutes a different fabric.

Other master and slave devices can be connected to the system bus 914. As illustrated in FIG. 9, these devices can include a memory system 920 that can be in a separate IC package 902(2) and that includes the memory controller 916 and a memory array(s) 918, one or more input devices 922 (that can be in a separate IC package 902(3)), one or more output devices 924 (that can be in a separate IC package 902(4)), one or more network interface devices 926, and one or more display controllers 928 as examples. Each of the memory system 920, the one or more input devices 922, the one or more output devices 924, the one or more network interface devices 926 that can be in an IC package 902(5), and the one or more display controllers 928 can be provided in the same or different IC packages. The input device(s) 922 can include any type of input device, including, but not limited to, input keys, switches, voice processors, etc. The output device(s) 924 can include any type of output device, including, but not limited to, audio, video, other visual indicators, etc. The network interface device(s) 926 can be any device configured to allow exchange of data to and from a network 930. The network 930 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 926 can be configured to support any type of communications protocol desired.

The CPU 908 may also be configured to access the display controller(s) 928 over the system bus 914 to control information sent to one or more displays 932. The display controller(s) 928 sends information to the display(s) 932 to be displayed via one or more video processors 934, which process the information to be displayed into a format suitable for the display(s) 932. The display controller(s) 928 and video processor(s) 934 can be included as ICs in the same or different IC packages 902(5), 902(6), or in the same or different IC package 902, 902(1) containing the CPU 908, as examples. The display(s) 932 can include any type of display, including, but not limited to, a cathode ray tube (CRT), a liquid crystal display (LCD), a plasma display, a light emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or in another computer readable medium and executed by a processor or other processing device, or combinations of both. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware, and may reside, for example, in Random Access Memory (RAM), flash memory, Read Only Memory (ROM), Electrically Programmable ROM (EPROM), Electrically Erasable Programmable ROM (EEPROM), registers, a hard disk, a removable disk, a CD-ROM, or any other form of computer readable medium known in the art. An exemplary storage medium is coupled to the processor such that the processor can read information from, and write information to, the storage medium. In the alternative, the storage medium may be integral to the processor. The processor and the storage medium may reside in an ASIC. The ASIC may reside in a remote station. In the alternative, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in a number of different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using any of a variety of different technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein, but is to be accorded the widest scope consistent with the principles and novel features disclosed herein.

Implementation examples are described in the following numbered clauses:
1. A package substrate, comprising:
   a first substrate, comprising:
      a first film metallization layer comprising a first surface and extending in a first direction, the first film metallization layer comprising:
         a first film insulating layer; and
         a first metal layer, comprising: a plurality of first metal interconnects exposed from the first surface in a first region of the first film metallization layer; and a plurality of second metal interconnects exposed from the first surface in a second region of the first film metallization layer adjacent to the first region in the first direction;
   a second substrate, comprising:
      a first pre-impregnated (PPG) metallization layer adjacent to the first surface in the second region, the first PPG metallization layer comprising:
         a second surface;
         a second insulating layer comprising a PPG material; and
         a second metal layer, comprising: a plurality of first metal pads exposed from the second surface.
2. The package substrate of clause 1, wherein the first substrate further comprises:
   a second film metallization layer adjacent to the first film metallization layer and extending in the first direction, the second film metallization layer comprising:
      a third surface;
      a second film insulating layer; and
      a third metal layer, comprising:
         a plurality of third metal interconnects exposed from the third surface; and
         a plurality of fourth metal interconnects exposed from the third surface;
   the first film metallization layer further comprising:
      a plurality of first vias each coupling a first metal interconnect of the plurality of first metal interconnects to a third metal interconnect of the plurality of third metal interconnects; and
      a plurality of second vias each coupling a second metal interconnect of the plurality of second metal interconnects to a fourth metal interconnect of the plurality of fourth metal interconnects.
3. The package substrate of clause 1 or 2, wherein the plurality of first metal interconnects has a first pitch less than or equal to five (5) micrometers (μm).
4. The package substrate of any of clauses 1-3, wherein the second substrate further comprises a plurality of first vias each coupling a first metal pad of the plurality of first metal pads to a second metal interconnect of the plurality of second metal interconnects.
5. The package substrate of any of clauses 1-4, wherein:
   the second substrate further comprises a second PPG metallization layer in the second region and adjacent to the first PPG metallization layer on an opposite side of the first PPG metallization layer;
   the second PPG metallization layer comprising:
      a third surface;
      a third PPG insulating layer comprising PPG material; and
      a third metal layer, comprising:
         a plurality of third metal interconnects exposed from the third surface;
   the first PPG metallization layer further comprises:
      a plurality of first vias each coupling a first metal pad of the plurality of first metal pads to a third metal interconnect of the plurality of third metal interconnects; and
   the second PPG metallization layer further comprises:
      a plurality of second vias each coupling a third metal interconnect of the plurality of third metal interconnects to a second metal interconnect of the plurality of second metal interconnects.
6. The package substrate of any of clauses 1-5, further comprising a solder resist layer adjacent to the first PPG metallization layer such that the first PPG metallization layer is between the solder resist layer and the first substrate in a second direction orthogonal to the first direction;
   the solder resist layer comprising a plurality of openings; and
   the plurality of first metal pads each exposed from an opening of the plurality of openings.
7. The package substrate of any of clauses 1-6, further comprising:
   a third substrate, comprising:
      a second film metallization layer adjacent to the first film metallization layer and extending in the first direction, the second film metallization layer comprising:
         a third surface;
         a second film insulating layer; and
         a third metal layer, comprising: a plurality of third metal interconnects exposed from the third surface; and a plurality of fourth metal interconnects exposed from the third surface; and
   a core layer between the first substrate and the third substrate in a second direction orthogonal to the first direction, the core layer comprising:
      a plurality of metal pillars each coupled to a first metal interconnect of the plurality of first metal interconnects, and to a third metal interconnect of the plurality of third metal interconnects.
8. The package substrate of any of clauses 1-6 not comprising a core layer.
9. The package substrate of any of clauses 1-8, wherein the first film insulating layer comprises a polyimide.
10. The package substrate of any of clauses 1-9, wherein a ratio of a second thickness of the second insulating layer in a second direction orthogonal to the first direction, to a first thickness of the first film insulating layer in the second direction is at least 1.5.
11. The package substrate of any of clauses 1-10, wherein:
   the first film insulating layer has a first thickness in a second direction orthogonal to the first direction between 10 micrometers (μm) and 35 μm; and
   the second insulating layer has a second thickness in the second direction between 15 μm and 45 μm.
12. The package substrate of any of clauses 1-11, wherein
   the first film insulating layer has a first modulus of elasticity; and
   the first PPG metallization layer has a second modulus of elasticity greater than the first modulus of elasticity.
13. The package substrate of any of clauses 1-12, wherein:
   the first film insulating layer has a first modulus of elasticity between 5 GigaPascal (GPa) and 20 GPa; and
   the first PPG metallization layer has a second modulus of elasticity between 14 GPa and 25 GPa.
14. The package substrate of any of clauses 1-13 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
15. A method of fabricating a package substrate, comprising:
   forming a first substrate, comprising:
      forming a first film metallization layer comprising a first surface and extending in a first direction, comprising:
         forming a first film insulating layer;
         forming a first metal layer;
         forming a plurality of first metal interconnects in the first metal layer exposed from the first surface in a first region of the first film metallization layer; and
         forming a plurality of second metal interconnects in the first metal layer exposed from the first surface in a second region of the first film metallization layer adjacent to the first region in the first direction;
   forming a second substrate, comprising:
      forming a first pre-impregnated (PPG) metallization layer having a second surface and comprising:
         forming a second insulating layer comprising a PPG material;
         forming a second metal layer; and
         forming a plurality of first metal pads from the second metal layer exposed from the second surface; and
   coupling the second substrate to the first substrate in a second direction orthogonal to the first direction in the second region of the first film metallization layer.
16. The method of clause 15, wherein:
   forming the second substrate further comprises forming a plurality of first vias each coupled a first metal pad of the plurality of first metal pads; and
   coupling the second substrate to the first substrate further comprises coupling a first via of the plurality of first vias to a second metal interconnect of the plurality of second metal interconnects.
17. The package substrate of clause 15 or 16, wherein coupling the second substrate to the first substrate in the second region further comprises laminating the second substrate on the first substrate.
18. The package substrate of any of clauses 15-17, further comprising providing an opening in the second substrate such that coupling the second substrate to the first substrate in the second region of the first substrate does not couple the second substrate to the first, die region of the first substrate.
19. The method of any of clauses 16-18, further comprising:
   forming a solder resist layer adjacent to the first PPG metallization layer such that the first PPG metallization layer is between the solder resist layer and the first substrate in the second direction; and
   forming a plurality of openings in the solder resist layer each exposing a first metal pad of the plurality of first metal pads.
20 The package substrate of clause 19, further comprising forming a second opening in the solder resist layer to expose the plurality of first metal interconnects.
21. An integrated circuit (IC) package, comprising:
   a package substrate, comprising:
      a first substrate, comprising:
         a first film metallization layer comprising a first surface and extending in a first direction, the first film metallization layer comprising: a first film insulating layer; and a first metal layer, comprising: a plurality of first metal interconnects exposed from the first surface in a first region of the first film metallization layer; and a plurality of second metal interconnects exposed from the first surface in a second region of the first film metallization layer adjacent to the first region in the first direction;
   a second substrate, comprising:
      a first pre-impregnated (PPG) metallization layer adjacent to the first surface in the second region, the first PPG metallization layer comprising:
         a second surface;
         a second insulating layer comprising a PPG material; and
         a second metal layer, comprising: a plurality of first metal pads exposed from the second surface;
   a first die comprising a plurality of die interconnects each connected to a first metal interconnect of the plurality of first metal interconnects; and
   a second die adjacent to the first die such that the first die is between the second die and the package substrate in a second direction orthogonal to the first direction; and
   a plurality of wire bonds each connected to the second die and a first metal pad of the plurality of first metal pads.
22. The IC package of clause 21, wherein the second substrate further comprises a plurality of first vias each coupling a first metal pad of the plurality of first metal pads to a second metal interconnect of the plurality of second metal interconnects.
23. The IC package of clause 21 or 22, wherein the package substrate further comprises:
   a third substrate, comprising:
      a second film metallization layer adjacent to the first film metallization layer and extending in the first direction, the second film metallization layer comprising:
         a third surface;
         a second film insulating layer; and
         a third metal layer, comprising: a plurality of third metal interconnects exposed from the third surface; and a plurality of fourth metal interconnects exposed from the third surface; and
   a core layer between the first substrate and the third substrate in a second direction orthogonal to the first direction, the core layer comprising:
      a plurality of metal pillars each coupled to a first metal interconnect of the plurality of first metal interconnects, and to a third metal interconnect of the plurality of third metal interconnects.
24. The IC package of clause 21 or 22 not comprising a core layer.
25. The IC package of any of clauses 21-24, wherein:
   the first film insulating layer has a first modulus of elasticity; and
   the first PPG metallization layer has a second modulus of elasticity greater than the first modulus of elasticity.
26. The IC package of any of clauses 21-25, wherein:
   the first film insulating layer has a first modulus of elasticity between 5 GigaPascal (GPa) and 20 GPa; and
   the first PPG metallization layer has a second modulus of elasticity between 14 GPa and 25 GPa.
27. The IC package of any of clauses 21-26 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

What is claimed is:

1. A package substrate, comprising:
a first substrate, comprising:
a first film metallization layer comprising a first surface and extending in
a first direction, the first film metallization layer comprising:
a first film insulating layer; and
a first metal layer, comprising:
a plurality of first metal interconnects exposed from the first surface in a first region of the first film metallization layer; and
a plurality of second metal interconnects exposed from the first surface in a second region of the first film metallization layer adjacent to the first region in the first direction;
a second substrate, comprising:
a first pre-impregnated (PPG) metallization layer adjacent to the first surface in the second region, the first PPG metallization layer comprising:
a second surface;
a second insulating layer comprising a PPG material; and
a second metal layer, comprising:
a plurality of first metal pads exposed from the second surface.

2. The package substrate of claim 1, wherein the first substrate further comprises:
a second film metallization layer adjacent to the first film metallization layer and extending in the first direction, the second film metallization layer comprising:
a third surface;
a second film insulating layer; and
a third metal layer, comprising:
a plurality of third metal interconnects exposed from the third surface; and
a plurality of fourth metal interconnects exposed from the third surface;
the first film metallization layer further comprising:
a plurality of first vias each coupling a first metal interconnect of the plurality of first metal interconnects to a third metal interconnect of the plurality of third metal interconnects; and
a plurality of second vias each coupling a second metal interconnect of the plurality of second metal interconnects to a fourth metal interconnect of the plurality of fourth metal interconnects.

3. The package substrate of claim 1, wherein the plurality of first metal interconnects has a first pitch less than or equal to five (5) micrometers (μm).

4. The package substrate of claim 1, wherein the second substrate further comprises a plurality of first vias each coupling a first metal pad of the plurality of first metal pads to a second metal interconnect of the plurality of second metal interconnects.

5. The package substrate of claim 1, wherein:
the second substrate further comprises a second PPG metallization layer in the second region and adjacent to the first PPG metallization layer on an opposite side of the first PPG metallization layer;
the second PPG metallization layer comprising:
a third surface;
a third PPG insulating layer comprising PPG material; and
a third metal layer, comprising:
a plurality of third metal interconnects exposed from the third surface;
the first PPG metallization layer further comprises:
a plurality of first vias each coupling a first metal pad of the plurality of first metal pads to a third metal interconnect of the plurality of third metal interconnects; and
the second PPG metallization layer further comprises:
a plurality of second vias each coupling a third metal interconnect of the plurality of third metal interconnects to a second metal interconnect of the plurality of second metal interconnects.

6. The package substrate of claim 1, further comprising a solder resist layer adjacent to the first PPG metallization layer such that the first PPG metallization layer is between the solder resist layer and the first substrate in a second direction orthogonal to the first direction;
the solder resist layer comprising a plurality of openings; and
the plurality of first metal pads each exposed from an opening of the plurality of openings.

7. The package substrate of claim 1, further comprising:
a third substrate, comprising:
a second film metallization layer adjacent to the first film metallization layer and extending in the first direction, the second film metallization layer comprising:
a third surface;
a second film insulating layer; and
a third metal layer, comprising:
a plurality of third metal interconnects exposed from the third surface; and
a plurality of fourth metal interconnects exposed from the third surface; and
a core layer between the first substrate and the third substrate in a second direction orthogonal to the first direction, the core layer comprising:
a plurality of metal pillars each coupled to a first metal interconnect of the plurality of first metal interconnects, and to a third metal interconnect of the plurality of third metal interconnects.

8. The package substrate of claim 1 not comprising a core layer.

9. The package substrate of claim 1, wherein the first film insulating layer comprises a polyimide.

10. The package substrate of claim 1, wherein a ratio of a second thickness of the second insulating layer in a second direction orthogonal to the first direction, to a first thickness of the first film insulating layer in the second direction is at least 1.5.

11. The package substrate of claim 1, wherein:
the first film insulating layer has a first thickness in a second direction orthogonal to the first direction between 10 micrometers (μm) and 35 μm; and
the second insulating layer has a second thickness in the second direction between 15 μm and 45 μm.

12. The package substrate of claim 1, wherein
the first film insulating layer has a first modulus of elasticity; and
the first PPG metallization layer has a second modulus of elasticity greater than the first modulus of elasticity.

13. The package substrate of claim 1, wherein:
the first film insulating layer has a first modulus of elasticity between 5 GigaPascal (GPa) and 20 GPa; and
the first PPG metallization layer has a second modulus of elasticity between 14 GPa and 25 GPa.

14. The package substrate of claim 1 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

15. A method of fabricating a package substrate, comprising:
forming a first substrate, comprising:
forming a first film metallization layer comprising a first surface and extending in a first direction, comprising:
forming a first film insulating layer;
forming a first metal layer;
forming a plurality of first metal interconnects in the first metal layer exposed from the first surface in a first region of the first film metallization layer; and
forming a plurality of second metal interconnects in the first metal layer exposed from the first surface in a second region of the first film metallization layer adjacent to the first region in the first direction;
forming a second substrate, comprising:
forming a first pre-impregnated (PPG) metallization layer having a second surface and comprising:
forming a second insulating layer comprising a PPG material;
forming a second metal layer; and
forming a plurality of first metal pads from the second metal layer exposed from the second surface; and
coupling the second substrate to the first substrate in a second direction orthogonal to the first direction in the second region of the first film metallization layer.

16. The method of claim 15, wherein:
forming the second substrate further comprises forming a plurality of first vias each coupled a first metal pad of the plurality of first metal pads; and
coupling the second substrate to the first substrate further comprises coupling a first via of the plurality of first vias to a second metal interconnect of the plurality of second metal interconnects.

17. The package substrate of claim 15, wherein coupling the second substrate to the first substrate in the second region further comprises laminating the second substrate on the first substrate.

18. The package substrate of claim 15, further comprising providing an opening in the second substrate such that coupling the second substrate to the first substrate in the second region of the first substrate does not couple the second substrate to the first, die region of the first substrate.

19. The method of claim 16, further comprising:
forming a solder resist layer adjacent to the first PPG metallization layer such that the first PPG metallization layer is between the solder resist layer and the first substrate in the second direction; and
forming a plurality of openings in the solder resist layer each exposing a first metal pad of the plurality of first metal pads.

20. The package substrate of claim 19, further comprising forming a second opening in the solder resist layer to expose the plurality of first metal interconnects.

21. An integrated circuit (IC) package, comprising:
a package substrate, comprising:
a first substrate, comprising:
a first film metallization layer comprising a first surface and extending in a first direction, the first film metallization layer comprising:
a first film insulating layer; and
a first metal layer, comprising: a plurality of first metal interconnects exposed from the first surface in a first region of the first film metallization layer; and a plurality of second metal interconnects exposed from the first surface in a second region of the first film metallization layer adjacent to the first region in the first direction;
a second substrate, comprising:
a first pre-impregnated (PPG) metallization layer adjacent to the first surface in the second region, the first PPG metallization layer comprising:
a second surface;
a second insulating layer comprising a PPG material; and
a second metal layer, comprising: a plurality of first metal pads exposed from the second surface;
a first die comprising a plurality of die interconnects each connected to a first metal interconnect of the plurality of first metal interconnects; and
a second die adjacent to the first die such that the first die is between the second die and the package substrate in a second direction orthogonal to the first direction; and
a plurality of wire bonds each connected to the second die and a first metal pad of the plurality of first metal pads.

22. The IC package of claim 21, wherein the second substrate further comprises a plurality of first vias each coupling a first metal pad of the plurality of first metal pads to a second metal interconnect of the plurality of second metal interconnects.

23. The IC package of claim 21, wherein the package substrate further comprises:
a third substrate, comprising:
a second film metallization layer adjacent to the first film metallization layer and extending in the first direction, the second film metallization layer comprising:
a third surface;
a second film insulating layer; and
a third metal layer, comprising:
a plurality of third metal interconnects exposed from the third surface; and
a plurality of fourth metal interconnects exposed from the third surface; and
a core layer between the first substrate and the third substrate in a second direction orthogonal to the first direction, the core layer comprising:
a plurality of metal pillars each coupled to a first metal interconnect of the plurality of first metal interconnects, and to a third metal interconnect of the plurality of third metal interconnects.

24. The IC package of claim 21 not comprising a core layer.

25. The IC package of claim 21, wherein:
the first film insulating layer has a first modulus of elasticity; and
the first PPG metallization layer has a second modulus of elasticity greater than the first modulus of elasticity.

26. The IC package of claim 21, wherein:
the first film insulating layer has a first modulus of elasticity between 5 GigaPascal (GPa) and 20 GPa; and
the first PPG metallization layer has a second modulus of elasticity between 14 GPa and 25 GPa.

27. The IC package of claim 21 integrated into a device selected from the group consisting of: a set top box; an entertainment unit; a navigation device; a communications device; a fixed location data unit; a mobile location data unit; a global positioning system (GPS) device; a mobile phone; a cellular phone; a smart phone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.
